(19) United States
(12) Patent Application Publication
(10) Pub. No.: US 2014/0306219 A1
(43) Pub. Date: Oct. 16, 2014

(54) SEMICONDUCTOR DEVICE

(71) Applicant: Semiconductor Energy Laboratory Co., Ltd., Atsugi-shi (JP)

(72) Inventors: Shunpei YAMAZAKI, Setagaya (JP); Kenichi OKAZAKI, Tochigi (JP); Masahiro KATAYAMA, Tochigi (JP); Takashi HAMOCHI, Shimotsuga (JP)

(73) Assignee: Semiconductor Energy Laboratory Co., Ltd., Atsugi-shi (JP)

(21) Appl. No.: 14/246,418

(22) Filed: Apr. 7, 2014

(30) Foreign Application Priority Data
Apr. 10, 2013 (JP) 2013-081882

(51) Int. Cl. H01L 27/12

(52) U.S. Cl. CPC H01L 27/1225
USPC 257/43

(57) ABSTRACT

Provided is a semiconductor device including a resistor having an oxide semiconductor and a transistor having an oxide semiconductor over the same substrate. The semiconductor device includes the resistor and the transistor over the same substrate. The resistor includes at least a first oxide semiconductor layer. The transistor includes at least a second oxide semiconductor layer. The first oxide semiconductor layer and the second oxide semiconductor layer have the same composition, and the carrier density of the first oxide semiconductor layer is higher than the carrier density of the second oxide semiconductor layer. The carrier density of the first oxide semiconductor layer is higher than the carrier density of the second oxide semiconductor layer because the first oxide semiconductor layer is subjected to treatment for increasing oxygen vacancies and/or impurity concentration in the first oxide semiconductor layer.

### BACKGROUND OF THE INVENTION

1. Field of the Invention

One embodiment of the invention to be disclosed relates to a semiconductor device and a method for manufacturing the semiconductor device.

Note that a semiconductor device in this specification refers to all electronic devices which can function by utilizing semiconductor characteristics, and electro-optical devices, semiconductor circuits, and electronic devices are all semiconductor devices.

2. Description of the Related Art

Transistors used for most flat panel displays typified by a liquid crystal display device and a light-emitting display device are formed using silicon semiconductors such as amorphous silicon, single crystal silicon, and polycrystalline silicon provided over glass substrates. Further, such a transistor employing such a silicon semiconductor is used in integrated circuits (ICs) and the like.

In recent years, attention has been drawn to a technique in which, instead of a silicon semiconductor, a metal oxide exhibiting semiconductor characteristics is used in transistors. Note that in this specification, a metal oxide exhibiting semiconductor characteristics is referred to as an oxide semiconductor.

For example, such a technique is disclosed that a transistor is manufactured using a zinc oxide or an In—Ga—Zn-based oxide as an oxide semiconductor and the transistor is used as a switching element or the like in a pixel of a display device (see Patent Documents 1 and 2).

A driver circuit portion for driving a pixel portion of a display device includes elements such as a thin film transistor, a capacitor, and a resistor.

Patent Document 3 discloses a semiconductor device in which a channel-etched transistor having an oxide semiconductor in a pixel portion and a resistor having an oxide semiconductor in a driver circuit are formed in the same process.

### REFERENCE

### Patent Documents

[Patent Document 1] Japanese Published Patent Application No. 2007-123861
[Patent Document 2] Japanese Published Patent Application No. 2007-096055
[Patent Document 3] Japanese Published Patent Application No. 2010-171394

### SUMMARY OF THE INVENTION

An object of one embodiment of the present invention is to provide a semiconductor device in which a resistor and a transistor each including an oxide semiconductor are provided over the same substrate.

Another object of one embodiment of the present invention is to provide a highly reliable semiconductor device.

Note that the descriptions of these objects do not disturb the existence of other objects. An embodiment of the present invention does not have to attain all the above objects. Objects other than the above objects will be apparent from and can be derived from the description of the specification and the like.

One embodiment of the present invention is a semiconductor device including a resistor and a transistor over the same substrate. The resistor includes at least a first oxide semiconductor layer. The transistor includes at least a second oxide semiconductor layer. The first oxide semiconductor layer and the second oxide semiconductor layer have the same composition, and the carrier density of the first oxide semiconductor layer is higher than the carrier density of the second oxide semiconductor layer. The carrier density of the first oxide semiconductor layer is higher than the carrier density of the second oxide semiconductor layer because the first oxide semiconductor layer is subjected to treatment for increasing oxygen vacancies and/or the impurity concentration in the first oxide semiconductor layer. Specifically, the following structures can be employed for example.

One embodiment of the present invention is a semiconductor device including a resistor and a transistor over the same substrate. The resistor includes a first gate electrode, a first gate insulating layer over the first gate electrode, a first oxide semiconductor layer overlapping the first gate electrode over the first gate insulating layer, and a first source electrode and a first drain electrode connected to the first oxide semiconductor layer. The transistor includes a second gate electrode, a second gate insulating layer over the second gate electrode, a second oxide semiconductor layer overlapping the second gate electrode over the second gate insulating layer, and a second source electrode and a second drain electrode connected to the second oxide semiconductor layer. The first oxide semiconductor layer and the second oxide semiconductor layer have the same composition, and the carrier density of the first oxide semiconductor layer is higher than the carrier density of the second oxide semiconductor layer.

When the carrier densities of oxide semiconductor layers included in a resistor and a transistor formed over the same substrate are different as described above, an oxide semiconductor layer functioning as part of a resistor and an oxide semiconductor layer functioning as a channel of a transistor can be separately formed. The resistor includes three terminals of a gate electrode, a source electrode, and a drain electrode, and thus the resistance of the resistor can be controlled more freely.

Note that in this specification and the like, the expression that a first oxide semiconductor layer and a second oxide semiconductor layer have the same composition means that they include at least the same metal elements. For example, the case where the first oxide semiconductor layer and the second oxide semiconductor layer have the same metal elements and a proportion of oxygen or hydrogen is different is also in the category of “have the same composition”.

In addition, in a formation process of a semiconductor device, the proportion of a metal element of one of the first oxide semiconductor layer and the second oxide semiconductor layer might change. For example, in the case where an In—Ga—Zn-based oxide is used for the first oxide semiconductor layer and plasma treatment or the like is performed on the first oxide semiconductor layer, the content of Zn in the first oxide semiconductor layer might be different before and after the plasma treatment. Thus, the expression “have the same metal elements” means that the same metal elements are contained as main components and the content of the same metal elements is substantially the same.

One embodiment of the present invention can provide a semiconductor device in which a resistor having an oxide semiconductor and a transistor having an oxide semiconductor are formed over the same substrate.

Further, one embodiment of the present invention can provide a highly reliable semiconductor device.

### BRIEF DESCRIPTION OF THE DRAWINGS

FIGS. 1A to 1C are plan views and a cross-sectional view illustrating one embodiment of a semiconductor device.

FIGS. 2A to 2D are cross-sectional views illustrating one embodiment of a manufacturing method of a semiconductor device.

FIGS. 3A to 3D are cross-sectional views illustrating one embodiment of a manufacturing method of a semiconductor device.

FIGS. 4A to 4C are cross-sectional views each illustrating one embodiment of a semiconductor device.

FIGS. 5A to 5C are cross-sectional views and a band diagram illustrating one embodiment of a semiconductor device.

FIGS. 6A to 6C are circuit diagrams illustrating one embodiment of a semiconductor device.

FIG. 7 is a cross-sectional view illustrating one embodiment of a semiconductor device.

FIGS. 8A to 8H are diagrams illustrating an electronic device.

FIGS. 9A to 9C are cross-sectional views illustrating samples of Example.

FIG. 10 shows measurement results of sheet resistance of oxide semiconductor layers.

FIG. 11 show results of ESR measurement performed on oxide semiconductor layers.

FIGS. 12A and 12B illustrate hydrogen concentrations of oxide semiconductor layers.

### DETAILED DESCRIPTION OF THE INVENTION

Embodiments of the present invention will be described below in detail with reference to the drawings. Note that the present invention is not limited to the description below, and it is easily understood by those skilled in the art that various changes and modifications can be made without departing from the spirit and scope of the invention. Accordingly, the present invention should not be interpreted as being limited to the content of the embodiment below. In addition, in the following embodiments, the same portions or portions having similar functions are denoted by the same reference numerals or the same hatching patterns in different drawings, and description thereof will not be repeated.

Note that in each drawing described in this specification, the size, the film thickness, or the region of each component may be exaggerated for clarity. Therefore, embodiments of the present invention are not limited to such a scale.

In this specification and the like, ordinal numbers such as “first” and “second” are used in order to avoid confusion among components, and the terms do not limit the components numerically. Therefore, for example, the term “first” can be replaced with the term “second”, “third”, or the like as appropriate.

Note that functions of a “source” and a “drain” of a transistor are sometimes replaced with each other when a transistor of opposite polarity is used or when the direction of current flowing is changed in circuit operation, for example. Therefore, the terms “source” and “drain” can be used to denote the drain and the source, respectively, in this specification.

### Embodiment 1

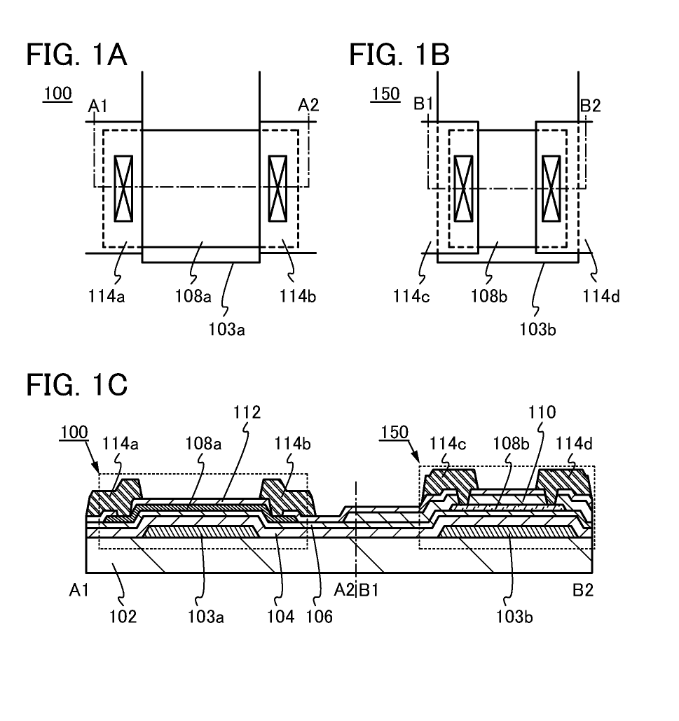

In this embodiment, a semiconductor device and a manufacturing method of the semiconductor device according to one embodiment of the present invention will be described with reference to FIGS. 1A to 1C, FIGS. 2A to 2D, FIGS. 3A to 3D, and FIGS. 4A to 4C.

### Structure Example of Semiconductor Device

FIGS. 1A to 1C illustrate structural examples of a semiconductor device. FIG. 1A is a plan view of a resistor 100 included in a semiconductor device. FIG. 1B is a plan view of a transistor 150 included in the semiconductor device. FIG. 1C is a cross-sectional view taken along line A1-A2 in FIG. 1A and line B1-B2 in FIG. 1B. Note that in FIGS. 1A and 1B, some components (e.g., insulating layers 104 and 106) of the resistor 100 and the transistor 150 are omitted for simplicity.

The resistor 100 in FIGS. 1A and 1C includes a first gate electrode 103a over a substrate 102, insulating layers 104 and 106 over the first gate electrode 103a, a first oxide semiconductor layer 108a overlapping the first gate electrode 103a over the insulating layer 106, an insulating layer 112 covering the first oxide semiconductor layer 108a, a first source electrode 114a and a first drain electrode 114b which are electrically connected to the first oxide semiconductor layer 108a in openings in the insulating layer 112.

Note that the resistor 100 in FIGS. 1A and 1C can serve as a variable resistor. For example, by applying voltage to the first gate electrode 103a, carriers in the first oxide semiconductor layer 108a can be controlled appropriately.

The transistor 150 in FIGS. 1B and 1C includes a second gate electrode 103b over the substrate 102, the insulating layers 104 and 106 over the second gate electrode 103b, a second oxide semiconductor layer 108b overlapping the second gate electrode 103b over the insulating layer 106, an insulating layer 110 and the insulating layer 112 covering the second oxide semiconductor layer 108b, a second source electrode 114c and a second drain electrode 114d which are electrically connected to the second oxide semiconductor layer 108b in openings in the insulating layers 110 and 112.

The insulating layers 104 and 106 are shared between the resistor 100 and the transistor 150. The insulating layers 104 and 106 in a position overlapping with the first gate electrode 103a serve as a gate insulating layer of the resistor 100. The insulating layers 104 and 106 in a position overlapping with the second gate electrode 103b serve as a gate insulating layer of the transistor 150. In FIG. 1C, the gate insulating layer has a stacked-layer structure of the insulating layer 104 and the insulating layer 106; however, the gate insulating layer may have a single-layer structure or a stacked-layer structure of three or more layers.

The first oxide semiconductor layer 108a and the second oxide semiconductor layer 108b are layers processed into island-like shapes by the same film formation step and the same etching step. An oxide semiconductor is a semiconductor material whose resistance can be controlled by oxygen vacancies in the film of the semiconductor material and/or the concentration of impurities such as hydrogen or water in the film of the semiconductor material. Thus, each resistivity of the oxide semiconductor layers formed in the same step can be controlled by selecting which treatment is performed on the first oxide semiconductor layer 108a and the second oxide semiconductor layer 108b: treatment for increasing oxygen vacancies and/or impurity concentration or treatment for reducing oxygen vacancies and/or impurity concentration.

Specifically, plasma treatment is performed on the first oxide semiconductor layer 108a included in the resistor 100 to increase oxygen vacancies and/or impurities such as hydrogen or water in the first oxide semiconductor layer 108a, so that the carrier density can be increased and the resistance can be lower than that of the second oxide semiconductor layer 108b. On the other hand, the insulating layer 110 is provided to prevent the second oxide semiconductor layer 108b of the transistor 150 from being subjected to the plasma treatment. The insulating layer 110 can be formed as an insulating layer capable of releasing oxygen, in which case oxygen can be supplied to the second oxide semiconductor layer 108b. The second oxide semiconductor layer 108b to which oxygen is supplied becomes an oxide semiconductor in which oxygen vacancies in the film or at the interface are filled which has higher resistance than the first oxide semiconductor layer 108a. Note that as the insulating layer capable of releasing oxygen, a silicon oxide film or a silicon oxynitride film can be used, for example.

As the plasma treatment on the first oxide semiconductor layer 108a, plasma treatment using a gas containing one of a rare gas (He, Ne, Ar, Kr, or Xe), hydrogen, and nitrogen is typical. Specifically, plasma treatment in an Ar atmosphere, plasma treatment in a mixed gas of Ar and hydrogen, plasma treatment in an ammonia atmosphere, plasma treatment in a mixed gas of Ar and ammonia, plasma treatment in a nitrogen atmosphere, or the like can be employed.

The hydrogen concentration and the number of oxygen vacancies in the first oxide semiconductor layer 108a might be changed after the plasma treatment.

The hydrogen concentration of the first oxide semiconductor layer 108a is higher than or equal to 1×10¹⁵ atoms/cm³; and the number of oxygen vacancies in the first oxide semiconductor layer 108a is more than 1×10¹⁵/cm³ and less than 1×10¹⁸/cm³, preferably more than 1×10¹⁶/cm³ and less than 1×10¹⁸/cm³. Alternatively, the hydrogen concentration of the first oxide semiconductor layer 108a is higher than or equal to 1×10¹⁵ atoms/cm³ and lower than 1×10¹⁸ atoms/cm³, preferably higher than 1×10¹⁶ atoms/cm³ and lower than 1×10¹⁸ atoms/cm³; and the number of oxygen vacancies is more than 1×10¹⁵/cm³, preferably more than 1×10¹⁶/cm³. Alternatively, the hydrogen concentration of the first oxide semiconductor layer 108a is higher than or equal to 1×10¹⁵ atoms/cm³ and lower than 1×10¹⁸ atoms/cm³, preferably higher than 1×10¹⁶ atoms/cm³ and lower than 1×10¹⁸ atoms/cm³; and the number of oxygen vacancies is more than 1×10¹⁵/cm³ and less than 1×10¹⁸/cm³, preferably more than 1×10¹⁶/cm³ and less than 1×10¹⁸/cm³.

In the first oxide semiconductor layer 108a subjected to the plasma treatment, an oxygen vacancy is formed in a lattice from which oxygen is released (or in a portion from which oxygen is released). This oxygen vacancy can cause carrier generation. Further, when hydrogen is supplied from an insulating film which is in the vicinity of the first oxide semiconductor layer 108a, specifically, which is in contact with the lower surface or the upper surface of the first oxide semiconductor layer 108a, and the hydrogen is combined with the oxygen vacancy, an electron which is a carrier might be generated. As a result, the first oxide semiconductor layer 108a whose number of oxygen vacancies is increased by the plasma treatment has higher carrier density than the second oxide semiconductor layer 108b.

The second oxide semiconductor layer 108b in which oxygen vacancies are filled and the hydrogen concentration is reduced can be referred to as a highly purified intrinsic or substantially highly purified intrinsic oxide semiconductor layer. The term “substantially intrinsic” refers to the state where an oxide semiconductor layer has a carrier density lower than 1×10¹⁷/cm³, preferably lower than 1×10¹⁵/cm³, further preferably lower than 1×10¹³/cm³. A highly purified intrinsic or substantially highly purified intrinsic oxide semiconductor has few carrier generation sources, and thus has a low carrier density. Further, the second oxide semiconductor layer 108b which is highly purified intrinsic or substantially highly purified intrinsic has a low defect level density, and thus has a low trap level density in some cases.

Further, the highly purified intrinsic or substantially highly purified intrinsic second oxide semiconductor layer 108b has an extremely low off-state current; even when an element has a channel width of 1×10⁶ μm and a channel length (L) of 10 μm, the off-state current can be less than or equal to the measurement limit of a semiconductor parameter analyzer, i.e., less than or equal to 1×10⁻¹³ A, at a voltage (drain voltage) between a source electrode and a drain electrode of from 1 V to 10 V. Thus, the second transistor 150 whose channel region is formed in the second oxide semiconductor layer 108b has a small variation in electrical characteristics and high reliability.

In FIG. 1C, the insulating layer 110 is formed by selectively removing a region that overlaps the first oxide semiconductor layer 108a in the resistor 100. Hence, the first oxide semiconductor layer 108a is covered with the insulating layer that is different from the insulating layer covering the second oxide semiconductor layer 108b. The insulating layer covering the first oxide semiconductor layer 108a in the resistor 100 is an insulating layer containing hydrogen, namely, an insulating layer capable of releasing hydrogen. A nitride insulating film is typically used for the insulating layer capable of releasing hydrogen. The insulating layer capable of releasing hydrogen preferably has a hydrogen concentration of higher than or equal to 1×10²² atoms/cm³ in a film, in which case hydrogen can be contained in the first oxide semiconductor layer 108a effectively. In this manner, by performing the above-described plasma treatment and changing the material of the insulating film in contact with the oxide semiconductor layer, the resistance of the oxide semiconductor layers can be appropriately adjusted.

Hydrogen contained in the first oxide semiconductor layer 108a reacts with oxygen bonded to a metal atom to be water, and in addition, an oxygen vacancy is formed in a lattice from which oxygen is released (or a portion from which oxygen is released). Due to entry of hydrogen into the oxygen vacancy, an electron serving as a carrier is generated. Further, in some cases, bonding of part of hydrogen to oxygen bonded to a metal element causes generation of an electron serving as a carrier. Thus, the first oxide semiconductor layer 108a containing hydrogen has a carrier density higher than that of the second oxide semiconductor layer 108b.

It is preferable that hydrogen in the second oxide semiconductor layer 108b of the transistor 150, in which a channel region is formed, be reduced as much as possible. Specifically, in the second oxide semiconductor layer 108b, the hydrogen concentration which is measured by secondary ion mass spectrometry (SIMS) is set to 2×10²⁰ atoms/cm³ or lower, preferably 5×10¹⁹ atoms/cm³ or lower, further preferably 1×10¹⁹ atoms/cm³ or lower, still further preferably lower than 5×10¹⁸ atoms/cm³, yet still further preferably 1×10¹⁸ atoms/cm³ or lower, yet still further preferably 5×10¹⁷ atoms/cm³ or lower, and yet still further preferably 1×10¹⁶ atoms/cm³ or lower. On the other hand, the first oxide semiconductor layer 108a included in the resistor 100 is a low-resistance oxide semiconductor layer that has high hydrogen concentration or/and a large number of oxygen vacancies as compared to the second oxide semiconductor layer 108b.

### Example of Method for Manufacturing Semiconductor Device

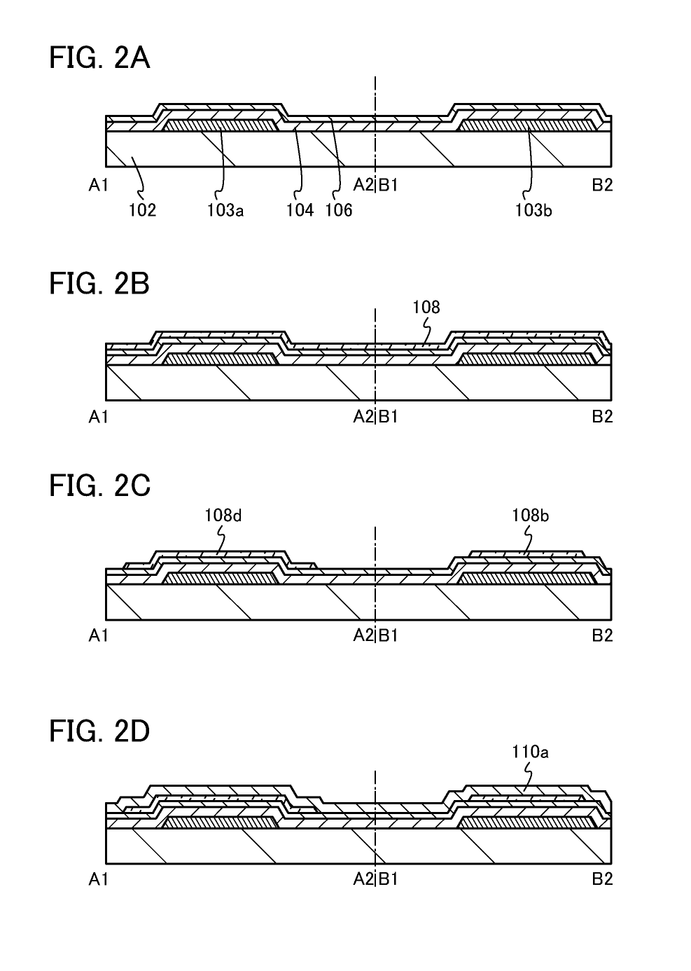

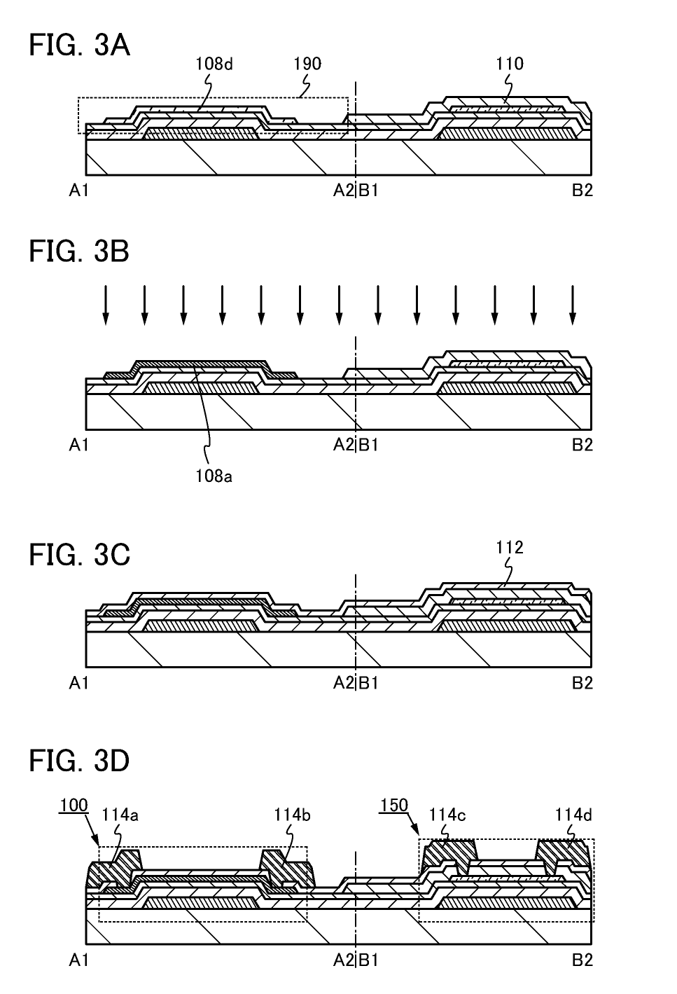

An example of a method for manufacturing a semiconductor device shown in FIGS. 1A to 1C is described with reference to FIGS. 2A to 2D and FIGS. 3A to 3D.

First, the first gate electrode 103a and the second gate electrode 103b are formed over the substrate 102, and then, the insulating layers 104 and 106 are formed over the first gate electrode 103a and the second gate electrode 103b (see FIG. 2A). Note that a wiring or the like may also be formed in the same step for forming the first gate electrode 103a and the second gate electrode 103b.

There is no particular limitation on the property of a material and the like of the substrate 102 as long as the material has heat resistance enough to withstand at least heat treatment to be performed later. For example, a glass substrate, a ceramic substrate, a quartz substrate, a sapphire substrate, or the like may be used as the substrate 102. Alternatively, a single crystal semiconductor substrate or a polycrystalline semiconductor substrate made of silicon, silicon carbide, or the like, a compound semiconductor substrate made of silicon germanium or the like, an SOI substrate, or the like may be used as the substrate 102. Furthermore, any of these substrates further provided with a semiconductor element may be used as the substrate 102. Still alternatively, any of these substrates provided with a semiconductor element may be used as the substrate 102. In the case where a glass substrate is used as the substrate 102, a glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

Still further alternatively, a flexible substrate may be used as the substrate 102, and the resistor 100 and the transistor 150 may be provided directly on the flexible substrate. Further alternatively, a separation layer may be provided between the substrate 102 and the resistor 100 and the transistor 150. The separation layer can be used when part or the whole of a semiconductor device formed over the separation layer is separated from the substrate 102 and transferred onto another substrate. In such a case, the resistor 100 and the transistor 150 can be transferred to a substrate having low heat resistance or a flexible substrate as well.

The first gate electrode 103a and the second gate electrode 103b may be formed using any of metal materials such as molybdenum, titanium, tantalum, tungsten, aluminum, copper, chromium, neodymium, and scandium, and an alloy material which contains any of these materials as its main component. Alternatively, a semiconductor film typified by a polycrystalline silicon film doped with an impurity element such as phosphorus, or a silicide film such as a nickel silicide film may be used as the first gate electrode 103a and the second gate electrode 103b. The first gate electrode 103a and the second gate electrode 103b can have a single-layer structure of a stacked-layer structure. The first gate electrode 103a and the second gate electrode 103b may have a tapered shape with a taper angle of greater than or equal to 15° and less than or equal to 70° for example. Here, the taper angle refers to an angle formed between a side surface of a layer having a tapered shape and a bottom surface of the layer.

The material of the first gate electrode 103a and the second gate electrode 103b may be a conductive material such as indium oxide-tin oxide, indium oxide containing tungsten oxide, indium zinc oxide containing tungsten oxide, indium oxide containing titanium oxide, indium tin oxide containing titanium oxide, indium oxide-zinc oxide, or indium tin oxide to which silicon oxide is added.

Alternatively, as the material of the first gate electrode 103a and the second gate electrode 103b, an In—Ga—Zn-based oxide containing nitrogen, an In—Sn-based oxide containing nitrogen, an In—Ga-based oxide containing nitrogen, an In—Zn-based oxide containing nitrogen, an Sn-based oxide containing nitrogen, an In-based oxide containing nitrogen, or a metal nitride film (such as an indium nitride film, a zinc nitride film, a tantalum nitride film, or a tungsten nitride film) may be used. These materials have a work function of 5 eV or more. Therefore, by forming the first gate electrode 103a and the second gate electrode 103b using any of these materials, the threshold voltage can be positive in the electrical characteristics of the transistor, so that the transistor can be a normally-off switching transistor.

The insulating layers 104 and 106 serve to a gate insulating layer of the resistor 100 and the transistor 150. As each of the insulating layers 104 and 106, an insulating layer including at least one of the following films formed by a plasma CVD method, a sputtering method, or the like can be used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. Note that the structure of the insulating layer is not limited to the stacked-layer structure of the insulating layer 104 and the insulating layer 106. An insulating layer with a single-layer structure including any of the above-described films can be used as the gate insulating layer.

Note that the insulating layer 106 that is in contact with the second oxide semiconductor layer 108b formed later is preferably an oxide insulating layer and preferably has a region (oxygen-excess region) containing oxygen in excess of the stoichiometric composition. To provide the oxygen-excess region in the insulating layer 106, the insulating layer 106 is formed in an oxygen atmosphere, for example. Alternatively, oxygen may be introduced into the deposited insulating layer 106 to provide the oxygen-excess region therein. As a method for introducing oxygen, an ion implantation method, an ion doping method, a plasma immersion ion implantation method, plasma treatment, or the like may be employed.

In this embodiment, a silicon nitride layer is formed as the insulating layer 104, and a silicon oxide layer is formed as the insulating layer 106. The relative dielectric constant of the silicon nitride layer is higher than that of the silicon oxide layer, and the silicon nitride layer needs to have a larger film thickness than the silicon oxide layer to obtain an equivalent capacitance. Thus, when the silicon nitride layer is included in the insulating layer 104 serving as the gate insulating layer of the resistor 100 and the transistor 150, the physical thickness of the gate insulating layer can be increased. This makes it possible to reduce a decrease in withstand voltage of the resistor 100 and the transistor 150 and furthermore to increase the withstand voltage, thereby reducing electrostatic discharge damage to the resistor and the transistor.

Next, the oxide semiconductor film 108 is formed over the insulating layer 106 (see FIG. 2B). The oxide semiconductor film 108 preferably includes a film represented by an In-M—Zn oxide that contains at least indium (In), zinc (Zn), and M (M is a metal such as Al, Ga, Ge, Y, Zr, Sn, La, Ce, or Hf). Alternatively, both In and Zn are preferably contained. In order to reduce fluctuations in electrical characteristics of the transistors including the oxide semiconductor, the oxide semiconductor preferably contains a stabilizer in addition to In and Zn.

As a stabilizer, gallium (Ga), tin (Sn), hafnium (Hf), aluminum (Al), zirconium (Zr), and the like can be given. As another stabilizer, lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) can be given.

As an oxide semiconductor included in the oxide semiconductor film 108, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, and an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

Note that here, for example, an “In—Ga—Zn-based oxide” means an oxide containing In, Ga, and Zn as its main components and there is no limitation on the ratio of In:Ga:Zn. The In—Ga—Z-based oxide may contain another metal element in addition to In, Ga, and Zn.

The oxide semiconductor film 108 can be formed by a sputtering method, a molecular beam epitaxy (MBE) method, a CVD method, a pulse laser deposition method, an atomic layer deposition (ALD) method, or the like as appropriate.

In the formation of the oxide semiconductor film 108, the hydrogen concentration in the oxide semiconductor film is preferably reduced as much as possible. To reduce the hydrogen concentration, for example, in the case of a sputtering method, a formation chamber needs to be highly evacuated and also a sputtering gas needs to be highly purified. As an oxygen gas or an argon gas used for a sputtering gas, a gas which is highly purified to have a dew point of −40° C. or lower, preferably −80° C. or lower, further preferably −100° C. or lower, still further preferably −120° C. or lower is used, whereby entry of moisture or the like into the oxide semiconductor film 108 can be prevented as much as possible.

In order to remove moisture remaining in the deposition chamber, an entrapment vacuum pump, such as a cryopump, an ion pump, or a titanium sublimation pump, is preferably used. The evacuation unit may be a turbo molecular pump provided with a cold trap. A cryopump has a high capability in removing a hydrogen molecule, a compound containing a hydrogen atom such as water (H₂O) (preferably, also a compound containing a carbon atom), and the like; thus, the impurity concentration in the film formed in the deposition chamber which is evacuated with the cryopump can be reduced.

Further, in the case where the oxide semiconductor film 108 is formed by a sputtering method, the relative density (the fill rate) of a metal oxide target which is used for forming the oxide semiconductor film is greater than or equal to 90% and less than or equal to 100%, preferably greater than or equal to 95% and less than or equal to 100%. With the use of the metal oxide target having high relative density, a dense oxide film can be formed.

Note that to reduce the impurity concentration in the oxide semiconductor film 108, it is also effective to form the oxide semiconductor film 108 while the substrate 102 is kept at high temperature. The heating temperature of the substrate 102 can be higher than or equal to 150° C. and lower than or equal to 450° C., and preferably the substrate temperature can be higher than or equal to 200° C. and lower than or equal to 350° C.

Next, the oxide semiconductor film 108 is processed into desired shapes, so that an island-shaped oxide semiconductor layer 108d and the second oxide semiconductor layer 108b are formed (see FIG. 2C).

The oxide semiconductor layer 108d, which becomes the first oxide semiconductor layer 108a later, and the second oxide semiconductor layer 108b are formed by processing the oxide semiconductor film 108; therefore, they contain at least the same metal elements. When the oxide semiconductor film 108 is processed by etching, a part of the insulating layer 106 (a region not covered with the second oxide semiconductor layer 108b and the oxide semiconductor layer 108d) might be etched to be thinned because of overetching of the oxide semiconductor film 108.

After the island-shaped oxide semiconductor layer 108d and the second oxide semiconductor layer 108b are formed, heat treatment is performed. The heat treatment is preferably performed at a temperature of higher than or equal to 250° C. and lower than or equal to 650° C., preferably higher than or equal to 300° C. and lower than or equal to 400° C., further preferably higher than or equal to 320° C. and lower than or equal to 370° C., in an inert gas atmosphere, an atmosphere containing an oxidizing gas at 10 ppm or more, or a reduced pressure atmosphere. Alternatively, the heat treatment may be performed in such a manner that heat treatment is performed in an inert gas atmosphere, and then another heat treatment is performed in an atmosphere containing an oxidizing gas at 10 ppm or more in order to compensate released oxygen. By the heat treatment, an impurity such as hydrogen or water can be removed from at least one of the insulating layer 104, the insulating layer 106, the oxide semiconductor layer 108d, and the second oxide semiconductor layer 108b. Note that the above-described heat treatment may be performed before the oxide semiconductor film 108 is processed into an island shape.

Note that stable electrical characteristics can be effectively imparted to the transistor 150 in which an oxide semiconductor serves as a channel by reducing the concentration of impurities in the oxide semiconductor to make the oxide semiconductor intrinsic or substantially intrinsic.

Next, an insulating film 110a is formed over the oxide semiconductor layer 108d and the second oxide semiconductor layer 108b (see FIG. 2D).

As the insulating film 110a, a silicon oxide film, a silicon oxynitride film, an aluminum oxide film, or the like having a thickness of from 150 nm to 400 nm can be used, for example. In this embodiment, a 300-nm-thick silicon oxynitride film is used as the insulating film 110a. The insulating film 110a can be formed by a CVD method, for example.

Then, the insulating film 110a is processed into desired regions so that an opening portion 190 is formed. In addition, the insulating film 110a serves as the insulating layer 110 including the opening portion 190 (see FIG. 3A).

The opening portion 190 is formed so as to expose the surface of the oxide semiconductor layer 108d. The opening portion 190 can be formed by dry etching, for example. Note that the method for forming the opening portion 190 is not limited to this. Wet etching may be used, or dry etching and wet etching may be combined. By the etching step for forming the opening portion 190, a part of the insulating layer 106 that is not covered with the insulating layer 110 and the oxide semiconductor layer 108d are thinned in some cases.

Heat treatment is preferably performed after that. By the heat treatment, part of oxygen contained in the insulating layer 110 can be moved to the second oxide semiconductor layer 108b to fill oxygen vacancies in the second oxide semiconductor layer 108b. Consequently, the number of oxygen vacancies in the second oxide semiconductor layer 108b can be reduced, while the number of oxygen vacancies in the oxide semiconductor layer 108d that is not in contact with the insulating layer 110 is not reduced. Thus, the number of oxygen vacancies in the oxide semiconductor layer 108d is larger than that in the second oxide semiconductor layer 108b. The heat treatment can be performed under conditions similar to those for the heat treatment performed after the formation of the oxide semiconductor layer 108d and the second oxide semiconductor layer 108b.

Next, plasma treatment is performed on the oxide semiconductor layer 108d. Specifically, plasma treatment is performed on the oxide semiconductor layer 108d and the insulating layers 106 and 110, so that the oxide semiconductor layer 108d becomes the first oxide semiconductor layer 108a having larger number of oxygen vacancies and/or higher impurity concentration (see FIG. 3B).

The arrow in FIG. 3B schematically denotes the plasma treatment. Plasma is applied to the vicinity of surfaces of the oxide semiconductor layer 108d and the insulating layers 106 and 110. As the plasma treatment, plasma treatment using a gas containing one of a rare gas (He, Ne, Ar, Kr, or Xe), hydrogen, and nitrogen is typical. Specifically, plasma treatment in an Ar atmosphere, plasma treatment in a mixed gas of Ar and hydrogen, plasma treatment in an ammonia atmosphere, plasma treatment in a mixed gas of Ar and ammonia, plasma treatment in a nitrogen atmosphere, or the like can be employed.

Because the number of oxygen vacancies in the oxide semiconductor layer 108d is increased due to the plasma damage or the gas species used in the plasma treatment is introduced into the oxide semiconductor layer 108d through the above plasma treatment, the resistance of the oxide semiconductor layer 108d is reduced. Thus, the oxide semiconductor layer 108d becomes the first oxide semiconductor layer 108a. Note that the resistance value of the oxide semiconductor layer 108d depends on the conditions for the plasma treatment. For example, in the conditions for plasma treatment in an Ar atmosphere, the number of oxygen vacancies in the oxide semiconductor layer 108d is increased by the plasma damage, so that the carrier density is increased and the resistance is decreased accordingly. In the conditions for plasma treatment in a mixed gas atmosphere containing Ar and hydrogen, the number of oxygen vacancies in the oxide semiconductor layer 108d is increased by the plasma damage and the oxygen vacancies are combined with hydrogen, so that the carrier density is increased and the resistance is further decreased.

When a gas used for plasma treatment, conditions for plasma treatment, time for plasma treatment, and the like are determined as described above by a practitioner, the resistivity of the first oxide semiconductor layer 108a is appropriately adjusted.

Note that a plasma CVD apparatus, an ashing apparatus, a sputtering apparatus, an etching apparatus, or the like can be used for the plasma treatment. In this embodiment, the plasma CVD apparatus is used and the plasma treatment is performed in an Ar atmosphere under the following conditions; the treatment pressure=200 Pa; the power=1 kW using an RF power source in the 27 MHz frequency band; the treatment time=300 sec; and the treatment temperature=350° C.

Note that the surface of the second oxide semiconductor layer 108b is protected by the insulating layer 110 when the plasma treatment illustrated in FIG. 3B is performed. Thus, the surface of the second oxide semiconductor layer 108b is not subjected to plasma in the plasma treatment, and an increase in oxygen vacancies and/or hydrogen concentration can be thus suppressed. In other words, the second oxide semiconductor layer 108b can be i-type or substantially i-type.

Next, the insulating layer 112 is formed over the insulating layer 110 and the first oxide semiconductor layer 108a (see FIG. 3C).

The insulating layer 112 contains hydrogen. When hydrogen contained in the insulating layer 112 diffuses into the first oxide semiconductor layer 108a, hydrogen is bonded to an oxygen vacancy in the first oxide semiconductor layer 108a, thereby producing an electron serving as a carrier. The resistivity of the first oxide semiconductor layer 108a is lower than at least the resistivity of the second oxide semiconductor layer 108b and is preferably higher than or equal to 1×10⁻³ Ωcm and lower than 1×10⁴ Ωcm, further preferably higher than or equal to 1×10⁻³ Ωcm and lower than 1×10⁻¹ Ωcm. Note that the insulating layer 112 also has an advantageous effect of preventing an external impurity such as water, alkali metal, or alkaline earth metal, from diffusing into the second oxide semiconductor layer 108b included in the transistor 150.

For example, a silicon nitride film, a silicon nitride oxide film, or the like having a thickness of from 50 nm to 400 nm can be used as the insulating layer 112. In this embodiment, a silicon nitride film having a thickness of 100 nm is used as the insulating layer 112.

The silicon nitride film is preferably formed at a high temperature to have an improved blocking property; for example, the silicon nitride film is preferably formed at temperatures ranging from the substrate temperature of 100° C. to the strain point of the substrate, more preferably at temperatures ranging from 300° C. to 400° C. When the silicon nitride film is formed at a high temperature, a phenomenon in which oxygen is released from the second oxide semiconductor layer 108b and the carrier density is increased is caused in some cases; therefore, the upper limit of the temperature is a temperature at which the phenomenon is not caused.

Although the insulating layer 112 covering the first oxide semiconductor layer 108a contains hydrogen in this embodiment, the present invention is not limited to this example. For example, an insulating layer containing oxygen may be used as an insulating film covering the first oxide semiconductor layer 108a. Note that in the case where the insulating film covering the first oxide semiconductor layer 108a is an insulating layer containing oxygen and the insulating layer containing oxygen contains excess oxygen in the film, oxygen vacancies generated by the above plasma treatment in the first oxide semiconductor layer 108a might be filled with the excess oxygen. Thus, as the insulating layer containing oxygen, an oxide insulating layer from which oxygen is less diffused by heating is preferably used.

Next, openings reaching the first oxide semiconductor layer 108a and the second oxide semiconductor layer 108b are formed in the insulating layers 110 and 112. A conductive film is formed in the openings and over the insulating layer 112 and is processed to form the first source electrode 114a and the first drain electrode 114b of the resistor 100 and the second source electrode 114c and the second drain electrode 114d of the transistor 150 (see FIG. 3D).

The first source electrode 114a and the first drain electrode 114b of the resistor 100 and the second source electrode 114c and the second drain electrode 114d of the transistor 150 can be formed to have a single-layer structure or a stacked-layer structure using, as a conductive material, any of single metals such as aluminum, titanium, chromium, nickel, copper, yttrium, zirconium, molybdenum, silver, tantalum, and tungsten, or an alloy containing any of these single metals as its main component. For example, a two-layer structure in which a titanium film is stacked over an aluminum film, a two-layer structure in which a titanium film is stacked over a tungsten film, a two-layer structure in which a copper film is formed over a copper-magnesium-aluminum alloy film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and the like can be used. Note that a transparent conductive material containing indium oxide, tin oxide, or zinc oxide may be used. The conductive film can be formed by sputtering, for example.

Note that the openings reaching the first oxide semiconductor layer 108a included in the resistor 100 and the openings reaching the second oxide semiconductor layer 108b included in the second transistor 150 can be formed in one etching process. However, in some cases, a part of the first oxide semiconductor layer 108a is overetched by etching the insulating layer 110 for forming the openings that reach the second oxide semiconductor layer 108b. Thus, the thickness of each of the regions of the first oxide semiconductor layer 108a that are in contact with the first source electrode 114a and the first drain electrode 114b might be smaller than the thickness of the region of the first oxide semiconductor layer 108a that is in contact with the insulating layer 112.

Further, in some cases, a part of the second oxide semiconductor layer 108b is overetched by the formation of the openings that reach the second oxide semiconductor layer 108b. Thus, the thickness of each of the regions of the second oxide semiconductor layer 108b that are in contact with the second source electrode 114c and the second drain electrode 114d might be smaller than the thickness of the region of the second oxide semiconductor layer 108b that is in contact with the insulating layer 110.

Through the above-described process, the resistor 100 and the transistor 150 can be formed over the same substrate.

The resistance of the resistor 100 formed in the manufacturing process in this embodiment is reduced by performing the plasma treatment over the entire surface of the first oxide semiconductor layer 108a. Further, the resistance value can be controlled appropriately by adjusting the conditions for the plasma treatment. On the other hand, the surface of the second oxide semiconductor layer 108b included in the transistor 150 is protected by the insulating layer 110 when the plasma treatment is performed; thus, a reduction in resistance of the second oxide semiconductor layer 108b can be suppressed.

The first oxide semiconductor layer 108a included in the resistor 100 and the second oxide semiconductor layer 108b included in the transistor 150 can be formed in one film formation process and one etching process and can have different carrier densities by the plasma treatment. Thus, the number of steps of forming a semiconductor device can be reduced. The number of oxygen vacancies in the first oxide semiconductor layer 108a damaged by the plasma treatment is larger than at least that of the second oxide semiconductor layer 108b. The hydrogen concentration of the first oxide semiconductor layer 108a to which hydrogen is supplied by the plasma treatment and/or hydrogen contained in the nearby insulating film is supplied is higher than at least that of the second oxide semiconductor layer 108b. Thus, the first oxide semiconductor layer 108a has a higher carrier density than the second oxide semiconductor layer 108b.

Note that the insulating layers 110 and 112 also serve as channel protection films in the transistor 150.

### Modification Example 1

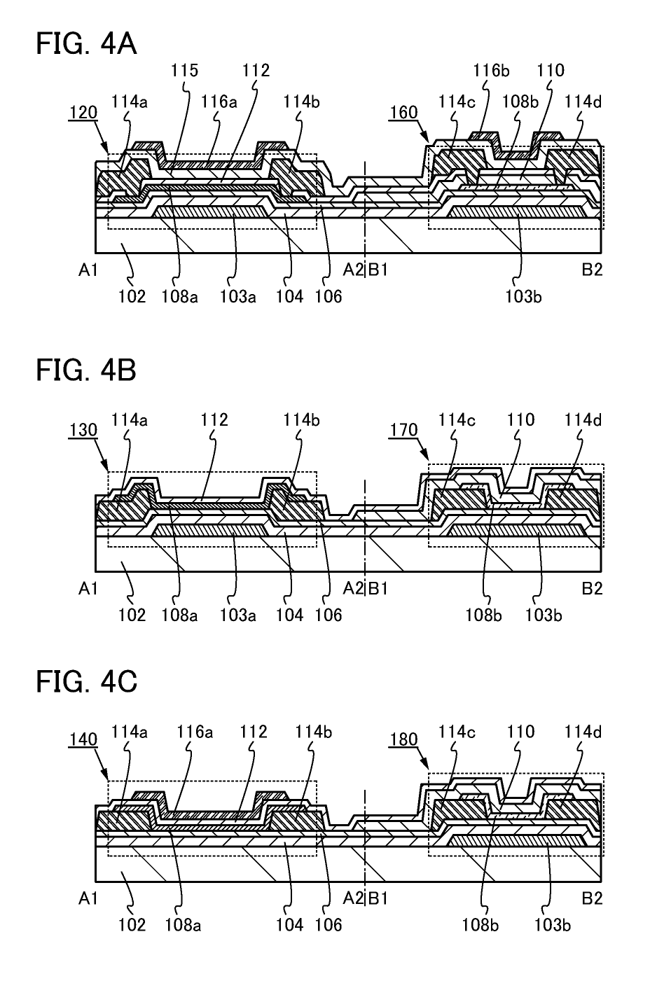

FIG. 4A shows modification examples of the resistor and the transistor that are included in the semiconductor device. A resistor 120 shown in FIG. 4A includes the first gate electrode 103a over the substrate 102, the insulating layers 104 and 106 over the first gate electrode 103a, the first oxide semiconductor layer 108a overlapping the first gate electrode 103a over the insulating layer 106, the insulating layer 112 covering the first oxide semiconductor layer 108a, the first source electrode 114a and the first drain electrode 114b electrically connected to the first oxide semiconductor layer 108a through the openings provided in the insulating layer 112, an interlayer insulating film 115 over the first source electrode 114a and the first drain electrode 114b, and a third gate electrode 116a overlapping the first oxide semiconductor layer 108a over the interlayer insulating film 115.

Note that the resistor 120 in FIG. 4A can serve as a variable resistor. For example, by applying voltage to the first gate electrode 103a and/or the third gate electrode 116a, carriers in the first oxide semiconductor layer 108a can be controlled appropriately. By providing two gate electrodes, the first gate electrode 103a and the third gate electrode 116a, with respect to the first oxide semiconductor layer 108a, carriers of the first oxide semiconductor layer 108a can be controlled more easily.

A transistor 160 shown in FIG. 4A includes the second gate electrode 103b over the substrate 102, the insulating layers 104 and 106 over the second gate electrode 103b, the second oxide semiconductor layer 108b overlapping the second gate electrode 103b over the insulating layer 106, the insulating layers 110 and 112 covering the second oxide semiconductor layer 108b, the second source electrode 114c and the second drain electrode 114d electrically connected to the second oxide semiconductor layer 108b through the openings provided in the insulating layers 110 and 112, the interlayer insulating film 115 over the second source electrode 114c and the second drain electrode 114d, and a fourth gate electrode 116b overlapping the second oxide semiconductor layer 108b over the interlayer insulating film 115.

The fourth gate electrode 116b functions as a back gate electrode of the transistor 160. For example, by applying voltage to the fourth gate electrode 116b, the threshold voltage of the transistor 160 can be controlled.

Note that the interlayer insulating film 115 overlapping the first oxide semiconductor layer 108a functions as a gate insulating layer for the third gate electrode 116a, and the interlayer insulating film 115 overlapping the second oxide semiconductor layer 108b functions as a gate insulating layer for the fourth gate electrode 116b.

The semiconductor device in FIG. 4A is different from the semiconductor device in FIGS. 1A to 1C in that the interlayer insulating film 115, the third gate electrode 116a, and the fourth gate electrode 116b are included. As in this structure, a plurality of gate electrodes may be provided in a resistor and a transistor. FIG. 4A illustrates a structure in which the resistor 120 and the transistor 160 each includes a gate electrode (the resistor 120 and the transistor 160 include the third gate electrode 116a and the fourth gate electrode 116b, respectively) over the interlayer insulating film 115. Note that without limitation to this structure, a structure in which only the resistor 120 includes a gate electrode (the third gate electrode 116a) or a structure in which only the transistor 160 includes a gate electrode (the fourth gate electrode 116b) may be used.

The interlayer insulating film 115 can be formed using a material and an apparatus that can be used for the insulating layers 104, 106, 110, and 112.

A material and an apparatus that can be used for the first gate electrode 103a and the second gate electrode 103b can be used to form the third gate electrode 116a and the fourth gate electrode 116b. In the case where the transistor 160 is used as a transistor in a pixel portion of a display device, for example, a material used for a pixel electrode is also used for the third gate electrode 116a and the fourth gate electrode 116b, in which case the formation step can be omitted.

A material having a property of transmitting visible light is used for the pixel electrode, for example. For example, a material containing one of indium (In), zinc (Zn), and tin (Sn) is preferably used. In addition, a light-transmitting conductive material such as indium oxide containing tungsten oxide, indium zinc oxide containing tungsten oxide, indium oxide containing titanium oxide, indium tin oxide containing titanium oxide, indium tin oxide (ITO), indium zinc oxide, or indium tin oxide to which silicon oxide is added can be used. The pixel electrode can be formed by a sputtering method, for example.

### Modification Example 2

FIG. 4B shows modification examples of the resistor and the transistor that are included in the semiconductor device. A resistor 130 shown in FIG. 4B includes the first gate electrode 103a over the substrate 102, the insulating layers 104 and 106 over the first gate electrode 103a, the first source electrode 114a and the first drain electrode 114b over the insulating layer 106, the first oxide semiconductor layer 108a overlapping the first gate electrode 103a over the insulating layer 106, the first source electrode 114a, and the first drain electrode 114b, and the insulating layer 112 covering the first oxide semiconductor layer 108a.

Note that the resistor 130 in FIG. 4B can serve as a variable resistor. For example, by applying voltage to the first gate electrode 103a, carriers in the first oxide semiconductor layer 108a can be controlled appropriately.

A transistor 170 shown in FIG. 4B includes the second gate electrode 103b over the substrate 102, the insulating layers 104 and 106 over the second gate electrode 103b, the second source electrode 114c and the second drain electrode 114d over the insulating layer 106, the second oxide semiconductor layer 108b overlapping the second gate electrode 103b over the insulating layer 106, the second source electrode 114c, and the second drain electrode 114d, and the insulating layers 110 and 112 covering the second oxide semiconductor layer 108b.

The positions of the source electrodes and the drain electrodes for the first oxide semiconductor layer 108a and the second oxide semiconductor layer 108b in the semiconductor device in FIG. 4B are different from those in the semiconductor device in FIGS. 1A to 1C. Specifically, in the resistor 130 in FIG. 4B, the first source electrode 114a and the first drain electrode 114b are in contact with the lower surface of the first oxide semiconductor layer 108a. In the transistor 170 in FIG. 4B, the second source electrode 114c and the second drain electrode 114d are in contact with the lower surface of the second oxide semiconductor layer 108b. As shown in FIG. 4B, a resistor and a transistor may each have a structure in which a source electrode and a drain electrode are in contact with the lower surface of an oxide semiconductor layer, that is, a bottom-contact structure.

### Modification Example 3

FIG. 4C shows modification examples of the resistor and the transistor that are included in the semiconductor device. A resistor 140 shown in FIG. 4C includes the insulating layers 104 and 106 over the substrate 102, the first source electrode 114a and the first drain electrode 114b over the insulating layer 106, the first oxide semiconductor layer 108a over the insulating layer 106, the first source electrode 114a, and the first drain electrode 114b, the insulating layer 112 covering the first oxide semiconductor layer 108a, and the third gate electrode 116a overlapping the first oxide semiconductor layer 108a over the insulating layer 112.

Note that the resistor 140 in FIG. 4C can serve as a variable resistor. For example, by applying voltage to the third gate electrode 116a, carriers in the first oxide semiconductor layer 108a can be controlled appropriately.

A transistor 180 shown in FIG. 4C includes the second gate electrode 103b over the substrate 102, the insulating layers 104 and 106 over the second gate electrode 103b, the second source electrode 114c and the second drain electrode 114d over the insulating layer 106, the second oxide semiconductor layer 108b overlapping the second gate electrode 103b over the insulating layer 106, the second source electrode 114c, and the second drain electrode 114d, and the insulating layers 110 and 112 covering the second oxide semiconductor layer 108b.

The positions of the source electrodes and the drain electrodes for the first oxide semiconductor layer 108a and the second oxide semiconductor layer 108b in the semiconductor device in FIG. 4C, and the position of the gate electrode for the first oxide semiconductor layer 108a are different from those in the semiconductor device in FIGS. 1A to 1C. In the resistor 140 in FIG. 4C, the first source electrode 114a and the first drain electrode 114b are in contact with the lower surface of the first oxide semiconductor layer 108a. Further, the third gate electrode 116a is provided over the first oxide semiconductor layer 108a. That is, the resistor 140 has a top-gate bottom-contact structure. In the transistor 170 in FIG. 4C, the second source electrode 114c and the second drain electrode 114d are in contact with the lower surface of the second oxide semiconductor layer 108b.

### Modification Example 4

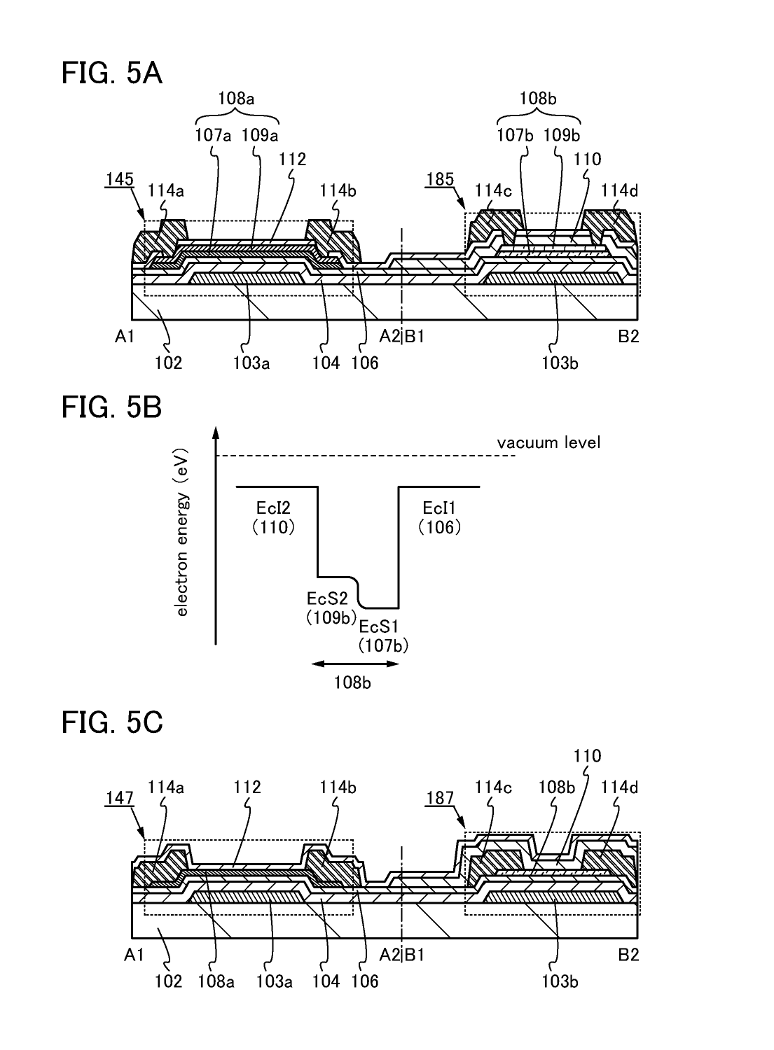

A resistor 145 shown in FIG. 5A is an example in which a stacked-layer structure of an oxide semiconductor layer 107a and an oxide semiconductor layer 109a is used instead of the first oxide semiconductor layer 108a in the resistor 100. Thus, the other components are the same as those of the resistor 100; hence, the above description can be referred to.

A transistor 185 shown in FIG. 5A is an example in which a stacked-layer structure of an oxide semiconductor layer 107b and an oxide semiconductor layer 109b is used instead of the second oxide semiconductor layer 108b in the transistor 150. Thus, the other components are the same as those of the transistor 150; hence, the above description can be referred to.

Metal oxide of the oxide semiconductor layers 107a and 107b (in this specification below, also referred to as oxide semiconductor layer 107) and metal oxide of the oxide semiconductor layers 109a and 109b (in this specification below, also referred to as oxide semiconductor layer 109) preferably have at least one constituent element in common. Alternatively, the constituent elements of the oxide semiconductor layer 107 and the oxide semiconductor layer 109 may be the same and the proportion of the constituent elements of the oxide semiconductor layer 107 and the oxide semiconductor layer 109 may be different.

In the case where the oxide semiconductor layer 107 is In-M—Zn oxide (M represents Al, Ga, Ge, Y, Zr, Sn, La, Ce, or Hf), it is preferable that the atomic ratio of metal elements of a sputtering target used for forming a film of the In-M—Zn oxide satisfy In≧M and Zn≧M. As the atomic ratio of metal elements of the sputtering target, In:M:Zn=1:1:1 and In:M:Zn=3:1:2 are preferable. Note that the proportion of the atomic ratio of the oxide semiconductor layer 107 formed using the above-described sputtering target varies within a range of ±20% as an error.

When the oxide semiconductor layer 107 is an In-M—Zn oxide, the atomic ratio of In to M when summation of In and M is assumed to be 100 atomic % is preferably as follows: the proportion of In is higher than or equal to 25 atomic % and the proportion of M is lower than 75 atomic %; more preferably, the proportion of In is higher than or equal to 34 atomic % and the proportion of M is lower than 66 atomic %.

The energy gap of the oxide semiconductor layer 107 is 2 eV or more, preferably 2.5 eV or more, further preferably 3 eV or more. The off-state current of the transistor 185 can be reduced by using an oxide semiconductor having a wide energy gap.

The thickness of the oxide semiconductor layer 107 is greater than or equal to 3 nm and less than or equal to 200 nm, preferably greater than or equal to 3 nm and less than or equal to 100 nm, further preferably greater than or equal to 3 nm and less than or equal to 50 nm.

The oxide semiconductor layer 109 is typically In—Ga oxide, In—Zn oxide, or In-M—Zn oxide (M represents Al, Ga, Ge, Y, Zr, Sn, La, Ce, or Hf). The energy at the conduction band bottom thereof is closer to a vacuum level than that of the oxide semiconductor layer 107 is, and typically, the difference between the energy at the conduction band bottom of the oxide semiconductor layer 109 and the energy at the conduction band bottom of the oxide semiconductor layer 107 is any one of 0.05 eV or more, 0.07 eV or more, 0.1 eV or more, and 0.15 eV or more, and any one of 2 eV or less, 1 eV or less, 0.5 eV or less, and 0.4 eV or less. That is, the difference between the electron affinity of the oxide semiconductor layer 109 and the electron affinity of the oxide semiconductor layer 107 is greater than or equal to 0.05 eV, greater than or equal to 0.07 eV, greater than or equal to 0.1 eV, or greater than or equal to 0.15 eV and also less than or equal to 2 eV, less than or equal to 1 eV, less than or equal to 0.5 eV, or less than or equal to 0.4 eV.

When the oxide semiconductor layer 109 contains a larger amount of the element M in an atomic ratio than the amount of In in an atomic ratio, any of the following effects may be obtained: (1) the energy gap of the oxide semiconductor layer 109 is widened; (2) the electron affinity of the oxide semiconductor layer 109 decreases; (3) an impurity from the outside is blocked; (4) an insulating property increases as compared to the oxide semiconductor layer 107. Further, oxygen vacancies are less likely to be generated in the oxide semiconductor layer 109 containing a larger amount of M in an atomic ratio than the amount of In in an atomic ratio because M is a metal element which is strongly bonded to oxygen.

When an In-M—Zn oxide is used for the oxide semiconductor layer 109, the proportions of In and Mis preferably as follows: the atomic percentage of In is less than 50 at. % and the atomic percentage of M is greater than or equal to 50 at. %; further preferably, the atomic percentage of In is less than 25 at. % and the atomic percentage of Mis greater than or equal to 75 at. %.

Further, in the case where each of the oxide semiconductor layer 107 and the oxide semiconductor layer 109 is In-M—Zn oxide (Mrepresents Al, Ga, Ge, Y, Zr, Sn, La, Ce, or Hf), the proportion of M atoms in the oxide semiconductor layer 109 is higher than the proportion of M atoms in the oxide semiconductor layer 107. Typically, the proportion of M atoms in the oxide semiconductor layer 209 is higher than or equal to 1.5 times, preferably higher than or equal to 2 times, further preferably higher than or equal to 3 times as large as that in the oxide semiconductor layer 107.

In the case where the oxide semiconductor layer 109 has an atomic ratio of In to M and Zn which is x₁:y₁:z₁ and the oxide semiconductor layer 107 has an atomic ratio of In to M and Zn which is x₂:y₂:z₂, y₁/x₁ is larger than y_{z}/x₂, preferably y₁/x₁ is 1.5 times or more as large as y₂/x₂. It is further preferable that y₁/x₁ be twice or more as large as y₂/x₂. It is still further preferable that y₁/x₁ be three or more times as large as y₂/x₂. In this case, it is preferable that in the oxide semiconductor layer, y₂ be higher than or equal to x₂ because the transistor 185 including the oxide semiconductor layer can have stable electric characteristics. However, when y₂ is larger than or equal to three or more times x₂, the field-effect mobility of the transistor 185 including the oxide semiconductor layer is reduced. Thus, it is preferable that y₂ be lower than three times x₂.

Further, in the case where the oxide semiconductor layer 109 is an In-M—Zn oxide film, the atomic ratio of metal elements of a sputtering target used for forming the In-M—Zn oxide preferably satisfies M>In and Zn>0.5×M, and more preferably, Zn also satisfies Zn>M. As the atomic ratio of metal elements of the sputtering target, In:Ga:Zn=1:3:2, In:Ga:Zn=1:3:4, In:Ga:Zn=1:3:5, In:Ga:Zn=1:3:6, In:Ga:Zn=1:3:7, In:Ga:Zn=1:3:8, In:Ga:Zn=1:3:9, In:Ga:Zn=1:3:10, In:Ga:Zn=1:6:4, In:Ga:Zn=1:6:5, In:Ga:Zn=1:6:6, In:Ga:Zn=1:6:7, In:Ga:Zn=1:6:8, In:Ga:Zn=1:6:9, and In:Ga:Zn=1:6:10 are preferable. Note that the proportion of each metal element in the atomic ratio of each of the oxide semiconductor layer 107 and the oxide semiconductor layer 109 containing In or Ga formed using the above-described sputtering target varies within a range of ±20% as an error.

Note that, without limitation to the compositions and materials described above, a material with an appropriate composition may be used depending on required semiconductor characteristics and electrical characteristics (e.g., field-effect mobility and threshold voltage) of a transistor. Further, in order to obtain the required semiconductor characteristics of the transistor, it is preferable that the carrier density, the impurity concentration, the defect density, the atomic ratio of a metal element to oxygen, the interatomic distance, the density, and the like of the oxide semiconductor layer 107 be set to appropriate values.

Note that the oxide semiconductor layer 109 also functions as a film which relieves damage to the oxide semiconductor layer 107 at the time of forming the insulating layer 110 or 112 later. The thickness of the oxide semiconductor layer 109 is greater than or equal to 3 nm and less than or equal to 100 nm, preferably greater than or equal to 3 nm and less than or equal to 50 nm.

When silicon or carbon which is one of elements belonging to Group 14 is contained in the oxide semiconductor layer 107b in the transistor 185, the number of oxygen vacancies is increased, and the oxide semiconductor layer 107b is changed to an n-type. Thus, the concentration of silicon or carbon (the concentration is measured by SIMS) in the oxide semiconductor layer 107b or the concentration of silicon or carbon (the concentration is measured by SIMS) in the vicinity of the interface between the oxide semiconductor layer 109b and the oxide semiconductor layer 107b is set to be lower than or equal to 2×10¹⁸ atoms/cm³, preferably lower than or equal to 2×10¹⁷ atoms/cm³.

Further, the concentration of alkali metal or alkaline earth metal of the oxide semiconductor layer 107b, which is measured by SIMS, is lower than or equal to 1×10¹⁸ atoms/cm³, preferably lower than or equal to 2×10¹⁶ atoms/cm³. Alkali metal and alkaline earth metal might generate carriers when bonded to an oxide semiconductor, in which case the off-state current of the transistor might be increased. Therefore, it is preferable to reduce the concentration of alkali metal or alkaline earth metal of the oxide semiconductor layer 107b.

Further, when nitrogen is contained in the oxide semiconductor layer 107b, electrons serving as carriers are generated to increase the carrier density, so that the oxide semiconductor layer 107b easily becomes n-type. Thus, a transistor including an oxide semiconductor which contains nitrogen is likely to be normally on. For this reason, nitrogen in the oxide semiconductor film is preferably reduced as much as possible; the concentration of nitrogen which is measured by SIMS is preferably set to, for example, lower than or equal to 5×10¹⁸ atoms/cm³.

Note that in the transistor 185 shown in FIG. 5A, the oxide semiconductor layer 109 is provided between the oxide semiconductor layer 107 and the insulating layer 110. The oxide semiconductor layer 107 is positioned on the second gate electrode 103b side and serves as a main path of carriers. Hence, if trap states are formed between the oxide semiconductor layer 109 and the insulating layer 110 owing to impurities and defects, electrons flowing in the oxide semiconductor layer 107 are less likely to be captured by the trap states because there is a distance between the trap states and the oxide semiconductor layer 107. Accordingly, the amount of on-state current of the transistor 185 can be increased, and the field-effect mobility can be increased. When the electrons are captured by the trap states, the electrons become negative fixed charges. As a result, a threshold voltage of the transistor 185 fluctuates. However, by the distance between the oxide semiconductor layer 107 and the trap states, capture of the electrons by the trap states can be reduced, and accordingly a fluctuation of the threshold voltage can be reduced.

Note that the oxide semiconductor layer 107 and the oxide semiconductor layer 109 are not formed by simply stacking each layer, but are formed to form a continuous junction (here, in particular, a structure in which the energy of the bottom of the conduction band is changed continuously between each film). In other words, a stacked-layer structure in which there exist no impurity which forms a defect level such as a trap center or a recombination center at each interface is provided. If an impurity exists between the oxide semiconductor layer 107 and the oxide semiconductor layer 109 which are stacked, a continuity of the energy band is damaged, and the carrier is captured or recombined at the interface and then disappears.

In order to form such a continuous energy band, it is necessary to form films continuously without being exposed to air, with use of a multi-chamber deposition apparatus (sputtering apparatus) including a load lock chamber. It is preferable that each chamber of the sputtering apparatus be evacuated to a high vacuum (to the degree of about 1×10⁻⁴ Pa to 5×10⁻⁷ Pa) by an adsorption vacuum pump such as a cryopump so that water and the like acting as impurities of the oxide semiconductor layer are removed as much as possible. Alternatively, a turbo molecular pump and a cold trap are preferably combined so as to prevent a backflow of a gas, especially a gas containing carbon or hydrogen from an exhaust system to the inside of the chamber.

Next, a band structure of the stacked-layer structure included in the transistor 185 is described with reference to FIG. 5B.

FIG. 5B schematically shows a part of a band structure of the transistor 185. Here, the case where silicon oxide layers are provided as the insulating layer 106 and the insulating layer 110 is shown. In FIG. 5B, EcI1 denotes the energy of the bottom of the conduction band in the silicon oxide layer which is used as the insulating layer 106; EcS1 denotes the energy of the bottom of the conduction band in the oxide semiconductor layer 107b; EcS2 denotes the energy of the bottom of the conduction band in the oxide semiconductor layer 109b; and EcI2 denotes the energy of the bottom of the conduction band in the silicon oxide layer which is used as the insulating layer 110.

As illustrated in FIG. 5B, there is no energy barrier between the oxide semiconductor layer 107b and the oxide semiconductor layer 109b, and the energy level of the bottom of the conduction band gradually changes therebetween. In other words, the energy level of the bottom of the conduction band is continuously changed. This is because the oxide semiconductor layer 107b contains an element contained in the oxide semiconductor layer 109b and oxygen is transferred between the oxide semiconductor layer 107b and the oxide semiconductor layer 109b, so that a mixed layer is formed.

As shown in FIG. 5B, the oxide semiconductor layer 107b in the second oxide semiconductor layer 108b serves as a well and a channel region of the transistor including the second oxide semiconductor layer 108b is formed in the oxide semiconductor layer 107b. Note that since the energy of the bottom of the conduction band of the second oxide semiconductor layer 108b is continuously changed, it can be said that the oxide semiconductor layer 107b and the oxide semiconductor layer 109b are continuous.

Although trap states due to impurities or vacancies, which are derived from silicon, carbon, or the like as a constituent element of the insulating layer 110, are likely to be formed in the vicinity of the interface between the oxide semiconductor layer 109b and the insulating layer 110 as illustrated in FIG. 5B, the oxide semiconductor layer 107b can be distanced from the trap states owing to existence of the oxide semiconductor layer 109b. However, when the energy difference between EcS1 and EcS2 is small, an electron in the oxide semiconductor layer 107b might reach the trap level by passing over the energy difference. When the electron is captured by the trap state, it become negative fixed electric charge, so that the threshold voltage of the transistor is shifted to the positive side. Therefore, it is preferable that the energy difference between EcS1 and EcS2 be 0.1 eV or more, more preferably 0.15 eV or more because a change in the threshold voltage of the transistor is prevented and stable electrical characteristics are obtained.

Note that FIGS. 5A and 5B show an example where the oxide semiconductor layers in the resistor 100 and the transistor 150 shown in FIGS. 1A to 1C each have a stacked-layer structure. However, this embodiment is not particularly limited thereto. The oxide semiconductor layer in any of the semiconductor devices with the structures shown in FIGS. 4A to 4C may have a stacked-layer structure.

### Modification Example 5

FIG. 5C shows modification examples of the resistor and the transistor that are included in the semiconductor device. A resistor 147 shown in FIG. 5C includes the first gate electrode 103a over the substrate 102, the insulating layers 104 and 106 over the first gate electrode 103a, the first oxide semiconductor layer 108a overlapping the first gate electrode 103a over the insulating layer 106, the first source electrode 114a and the first drain electrode 114b over the first oxide semiconductor layer 108a, and the insulating layer 112 covering the first oxide semiconductor layer 108a, the first source electrode 114a, and the first drain electrode 114b.

Note that the resistor 147 in FIG. 5C can serve as a variable resistor. For example, by applying voltage to the first gate electrode 103a, carriers in the first oxide semiconductor layer 108a can be controlled appropriately.

A transistor 187 shown in FIG. 5C includes the second gate electrode 103b over the substrate 102, the insulating layers 104 and 106 over the second gate electrode 103b, the second oxide semiconductor layer 108b overlapping the second gate electrode 103b over the insulating layer 106, the second source electrode 114c and the second drain electrode 114d over the second oxide semiconductor layer 108b, and the insulating layers 110 and 112 covering the second oxide semiconductor layer 108b, the second source electrode 114c, and the second drain electrode 114d.

The positions of the insulating layers 110 and 112 in the semiconductor device in FIG. 5C are different from those in the semiconductor device in FIGS. 1A to 1C. Specifically, in the resistor 147 shown in FIG. 5C, the insulating layer 112 is formed over the first oxide semiconductor layer 108a, the first source electrode 114a, and the first drain electrode 114b. In the transistor 187, the insulating layers 110 and 112 are formed over the second oxide semiconductor layer 108b, the second source electrode 114c, and the second drain electrode 114d. That is, the resistor 147 and the transistor 187 each have a channel-etched top-contact structure.

In the case of the structure of the semiconductor device in FIG. 5C, the insulating layer 110 is formed in a desired region after the first source and drain electrodes 114a and 114b and the second source and drain electrodes 114c and 114d are formed. Then, plasma treatment is performed and/or the insulating layer 112 and the first oxide semiconductor layer 108a are in contact with each other, whereby the carrier density of the first oxide semiconductor layer 108a can be increased. Note that the regions of the first oxide semiconductor layer 108a over which the first source electrode 114a and the first drain electrode 114b are provided are not subjected to the plasma treatment and/or the first oxide semiconductor layer 108a is not in contact with the insulating layer 112 in the regions. However, because oxygen is not supplied from the insulating layer 110 to the regions, the resistance of the regions can be reduced.

When the carrier densities of oxide semiconductor layers included in a resistor and a transistor formed over the same substrate are different as described above, an oxide semiconductor layer functioning as part of a resistor and an oxide semiconductor layer functioning as a channel of a transistor can be separately formed. The resistor includes three terminals of a gate electrode, a source electrode, and a drain electrode, and thus the resistance of the resistor can be controlled more freely.

The structures, the methods, and the like described in this embodiment can be combined as appropriate with any of the structures, the methods, and the like described in the other embodiments.

### Embodiment 2

In this embodiment, an example of an oxide semiconductor layer that can be used for the transistor and the resistor in Embodiment 1 is described.

### <Crystallinity of Oxide Semiconductor Layer>

A structure of an oxide semiconductor layer is described below.

An oxide semiconductor layer is classified roughly into a non-single-crystal oxide semiconductor layer and a single crystal oxide semiconductor layer. The non-single-crystal oxide semiconductor layer includes a c-axis aligned crystalline oxide semiconductor (CAAC-OS) film, a polycrystalline oxide semiconductor layer, a microcrystalline oxide semiconductor layer, an amorphous oxide semiconductor layer, and the like.

First, a CAAC-OS film is described.

The CAAC-OS film is one of oxide semiconductor layers including a plurality of crystal parts, and most of the crystal parts each fits inside a cube whose one side is less than 100 nm. Thus, there is a case where a crystal part included in the CAAC-OS film fits inside a cube whose one side is less than 10 nm, less than 5 nm, or less than 3 nm.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor layer of InGaZnO₄, six peaks appear. The six peaks are derived from crystal planes equivalent to the (110) plane. However, in the case of a CAAC-OS film, a peak is not clearly observed even when φ scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned in a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appears at around 31° and a peak of 2θ do not appear at around 36°.

In this specification, the trigonal and rhombohedral crystal systems are included in the hexagonal crystal system.

The CAAC-OS film is an oxide semiconductor layer having a low impurity concentration. The impurity is any of elements which are not the main components of the oxide semiconductor layer and includes hydrogen, carbon, silicon, a transition metal element, and the like. In particular, an element (e.g., silicon) which has higher bonding strength with oxygen than a metal element included in the oxide semiconductor layer causes disorder of atomic arrangement in the oxide semiconductor layer because the element deprives the oxide semiconductor layer of oxygen, thereby reducing crystallinity. Further, a heavy metal such as iron or nickel, argon, carbon dioxide, and the like have a large atomic radius (or molecular radius); therefore, when any of such elements is contained in the oxide semiconductor layer, the element causes disorder of the atomic arrangement of the oxide semiconductor layer, thereby reducing crystallinity. Note that the impurity contained in the oxide semiconductor layer might become a carrier trap or a source of carriers.

The CAAC-OS film is an oxide semiconductor layer having a low density of defect states.

With the use of the CAAC-OS film in a transistor, variation in the electrical characteristics of the transistor due to irradiation with visible light or ultraviolet light is small.

Next, a microcrystalline oxide semiconductor layer is described.

In an image obtained with a TEM, for example, crystal parts cannot be found clearly in the microcrystalline oxide semiconductor layer in some cases. In most cases, the size of a crystal part included in the microcrystalline oxide semiconductor layer is greater than or equal to 1 nm and less than or equal to 100 nm, or greater than or equal to 1 nm and less than or equal to 10 nm, for example. A microcrystal with a size greater than or equal to 1 nm and less than or equal to 10 nm, or a size greater than or equal to 1 nm and less than or equal to 3 nm is specifically referred to as nanocrystal (nc). An oxide semiconductor layer including nanocrystal is referred to as an nc-OS (nanocrystalline oxide semiconductor) film. In an image obtained with TEM, a crystal grain cannot be found clearly in the nc-OS film in some cases.

In the nc-OS film, a macroscopic region (for example, a region with a size greater than or equal to 1 nm and less than or equal to 10 nm, in particular, a region with a size greater than or equal to 1 nm and less than or equal to 3 nm) has a periodic atomic order. Note that there is no regularity of crystal orientation between different crystal parts in the nc-OS film. Thus, the orientation of the whole film is not observed. Accordingly, in some cases, the nc-OS film cannot be distinguished from an amorphous oxide semiconductor depending on an analysis method. For example, when the nc-OS film is subjected to structural analysis by an out-of-plane method with an XRD apparatus using an X-ray having a diameter larger than that of a crystal part, a peak which shows a crystal plane does not appear. Further, a halo pattern is shown in a selected-area electron diffraction pattern of the nc-OS film obtained by using an electron beam having a probe diameter (e.g., larger than or equal to 50 nm) larger than that of a crystal part. Meanwhile, spots are shown in a nanobeam electron diffraction pattern of the nc-OS film obtained by using an electron beam having a probe diameter (e.g., larger than or equal to 1 nm and smaller than or equal to 30 nm) close to, or smaller than or equal to that of a crystal part. Further, in a nanobeam electron diffraction pattern of the nc-OS film, regions with high luminance in a circular (ring) pattern are observed in some cases. Also in a nanobeam electron diffraction pattern of the nc-OS film, a plurality of spots are shown in a ring-like region in some cases.

The nc-OS film is an oxide semiconductor layer that has high regularity as compared to an amorphous oxide semiconductor layer. Therefore, the nc-OS film has a lower density of defect states than an amorphous oxide semiconductor layer. Note that there is no regularity of crystal orientation between different crystal parts in the nc-OS film. However, there is no regularity of crystal orientation between different crystal parts in the nc-OS film; hence, the nc-OS film has a higher density of defect states than the CAAC-OS film.

Note that an oxide semiconductor layer may be a stacked film including two or more films of an amorphous oxide semiconductor layer, a microcrystalline oxide semiconductor layer, and a CAAC-OS film, for example.

### <Formation Method of the CAAC-OS Film>

For example, the CAAC-OS film is formed by a sputtering method with a polycrystalline oxide semiconductor sputtering target. When ions collide with the sputtering target, a crystal region included in the sputtering target may be separated from the target along an a-b plane; in other words, a sputtered particle having a plane parallel to an a-b plane (flat-plate-like sputtered particle or pellet-like sputtered particle) may flake off from the sputtering target. In that case, the flat-plate-like sputtered particle reaches a substrate while maintaining their crystal state, whereby the CAAC-OS film can be formed.

The flat-plate-like sputtered particle has, for example, an equivalent circle diameter of a plane parallel to the a-b plane of greater than or equal to 3 nm and less than or equal to 10 nm, and a thickness (length in the direction perpendicular to the a-b plane) of greater than or equal to 0.7 nm and less than 1 nm. Note that in the flat-plate-like sputtered particle, the plane parallel to the a-b plane may be a regular triangle or a regular hexagon. Here, the term “equivalent circle diameter of a plane” refers to the diameter of a perfect circle having the same area as the plane.

For the deposition of the CAAC-OS film, the following conditions are preferably used.

By increasing the substrate temperature during the deposition, migration of sputtered particles is likely to occur after the sputtered particles reach a substrate surface. Specifically, the substrate temperature during the deposition is higher than or equal to 100° C. and lower than or equal to 740° C., preferably higher than or equal to 200° C. and lower than or equal to 500° C. By increasing the substrate temperature during the deposition, when the flat-plate-like sputtered particles reach the substrate, migration occurs on the substrate surface, so that a flat plane of the sputtered particles is attached to the substrate. At this time, the sputtered particle is charged positively, whereby sputtered particles are attached to the substrate while repelling each other; thus, the sputtered particles do not overlap with each other randomly, and a CAAC-OS film with a uniform thickness can be deposited.

By reducing the amount of impurities entering the CAAC-OS layer during the deposition, the crystal state can be prevented from being broken by the impurities. For example, the concentration of impurities (e.g., hydrogen, water, carbon dioxide, or nitrogen) which exist in the deposition chamber may be reduced. Furthermore, the concentration of impurities in a deposition gas may be reduced. Specifically, a deposition gas whose dew point is −80° C. or lower, preferably −100° C. or lower is used.

Furthermore, it is preferable that the proportion of oxygen in the deposition gas be increased and the power be optimized in order to reduce plasma damage at the deposition. The proportion of oxygen in the deposition gas is higher than or equal to 30 vol %, preferably 100 vol %.

Alternatively, the CAAC-OS film is formed by the following method.

First, a first oxide semiconductor layer is formed to a thickness of greater than or equal to 1 nm and less than 10 nm. The first oxide semiconductor layer is formed by a sputtering method. Specifically, the substrate temperature is set to higher than or equal to 100° C. and lower than or equal to 500° C., preferably higher than or equal to 150° C. and lower than or equal to 450° C., and the proportion of oxygen in a deposition gas is set to higher than or equal to 30 vol %, preferably 100 vol %.

Then, heat treatment is performed to increase the crystallinity of the first oxide semiconductor layer to give the first CAAC-OS film with high crystallinity. The temperature of the heat treatment is higher than or equal to 350° C. and lower than or equal to 740° C., preferably higher than or equal to 450° C. and lower than or equal to 650° C. The heat treatment time is longer than or equal to 1 minute and shorter than or equal to 24 hours, preferably longer than or equal to 6 minutes and shorter than or equal to 4 hours. The heat treatment may be performed in an inert atmosphere or an oxidation atmosphere. It is preferable to perform heat treatment in an inert atmosphere and then perform heat treatment in an oxidation atmosphere. The heat treatment in an inert atmosphere can reduce the concentration of impurities in the first oxide semiconductor layer in a short time. At the same time, the heat treatment in an inert atmosphere may generate oxygen vacancies in the first oxide semiconductor layer. In such a case, the heat treatment in an oxidation atmosphere can reduce the oxygen vacancies. Note that the heat treatment may be performed under a reduced pressure, such as 1000 Pa or lower, 100 Pa or lower, 10 Pa or lower, or 1 Pa or lower. The heat treatment under the reduced pressure can reduce the concentration of impurities in the first oxide semiconductor layer in a shorter time.

The first oxide semiconductor layer with a thickness of greater than or equal to 1 nm and less than 10 nm can be easily crystallized by heat treatment as compared to the case where the first oxide semiconductor layer has a thickness of greater than or equal to 10 nm.

Next, a second oxide semiconductor layer having the same composition as the first oxide semiconductor layer is formed to a thickness of greater than or equal to 10 nm and less than or equal to 50 nm. The second oxide semiconductor layer is formed by a sputtering method. Specifically, the substrate temperature is set to higher than or equal to 100° C. and lower than or equal to 500° C., preferably higher than or equal to 150° C. and lower than or equal to 450° C., and the proportion of oxygen in a deposition gas is set to higher than or equal to 30 vol %, preferably 100 vol %.

Then, heat treatment is conducted so that the second oxide semiconductor layer is turned into a second CAAC-OS film with high crystallinity by solid phase growth from the first CAAC-OS film. The temperature of the heat treatment is higher than or equal to 350° C. and lower than or equal to 740° C., preferably higher than or equal to 450° C. and lower than or equal to 650° C. The heat treatment time is longer than or equal to 1 minute and shorter than or equal to 24 hours, preferably longer than or equal to 6 minutes and shorter than or equal to 4 hours. The heat treatment may be performed in an inert atmosphere or an oxidation atmosphere. It is preferable to perform heat treatment in an inert atmosphere and then perform heat treatment in an oxidation atmosphere. The heat treatment in an inert atmosphere can reduce the concentration of impurities in the second oxide semiconductor layer in a short time. At the same time, the heat treatment in an inert atmosphere may generate oxygen vacancies in the second oxide semiconductor layer. In such a case, the heat treatment in an oxidation atmosphere can reduce the oxygen vacancies. Note that the heat treatment may be performed under a reduced pressure, such as 1000 Pa or lower, 100 Pa or lower, 10 Pa or lower, or 1 Pa or lower. The heat treatment under the reduced pressure can reduce the concentration of impurities in the second oxide semiconductor layer in a shorter time.

As described above, a CAAC-OS film with a total thickness of greater than or equal to 10 nm can be formed. The CAAC-OS film can be favorably used as the oxide semiconductor layer in the oxide stack.

Next, a method for forming an oxide film in the case where a formation surface has a low temperature (e.g., a temperature lower than 130° C., lower than 100° C., or lower than 70° C., or approximately a room temperature (20° C. to 25° C.)) because, for example, the substrate is not heated is described.

In the case where the formation surface has a low temperature, sputtered particles fall irregularly to the deposition surface. For example, migration does not occur; therefore, the sputtered particles are randomly deposited on the deposition surface including a region where other sputtered particles have been deposited. That is, an oxide film obtained by the deposition might have a non-uniform thickness and a disordered crystal alignment. The oxide film obtained in the above manner maintains the crystallinity of the sputtered particles to a certain degree and thus has a crystal part (nanocrystal).

For example, in the case where the pressure at the deposition is high, the frequency with which the flying sputtered particle collides with another particle (e.g., an atom, a molecule, an ion, or a radical) of argon or the like is increased. When the flying sputtered particle collides with another particle (resputtered), the crystal structure of the sputtered particle might be broken. For example, when the sputtered particle collides with another particle, the plate-like shape of the sputtered particle cannot be kept, and the sputtered particle might be broken into parts (e.g., atomized). At this time, when atoms obtained from the sputtered particle are deposited on the formation surface, an amorphous oxide semiconductor film might be formed.

In addition, when a process in which a liquid is used or a process in which a solid target is vaporized is employed instead of a sputtering method using a polycrystalline oxide target as a starting point, separated atoms fly and are deposited on a deposition surface and thus an amorphous oxide film is formed in some cases. Further, for example, by a laser ablation method, atoms, molecules, ions, radials, clusters, or the like released from the target flies to be deposited over the formation surface; therefore, an amorphous oxide film might be formed.

In each of the resistor and the transistor of one embodiment of the present invention, an oxide semiconductor layer in any of the above crystal states may be used. Further, in the case of stacked oxide semiconductor layers, the crystal states of the oxide semiconductor layers may be different from each other. Note that the CAAC-OS film is preferably applied to the oxide semiconductor layer functioning as the channel of the transistor. Further, the oxide semiconductor layer included in the resistor has a higher impurity concentration than that of the oxide semiconductor layer included in the transistor; thus, the crystallinity is lowered in some cases.

The structures, the methods, and the like described in this embodiment can be combined as appropriate with any of the structures, the methods, and the like described in the other embodiments.

### Embodiment 3

In the present embodiment, a semiconductor device that is one embodiment of the present invention is described with reference to drawings. Note that in this embodiment, a semiconductor device of one embodiment of the present invention is described taking a display device as an example.

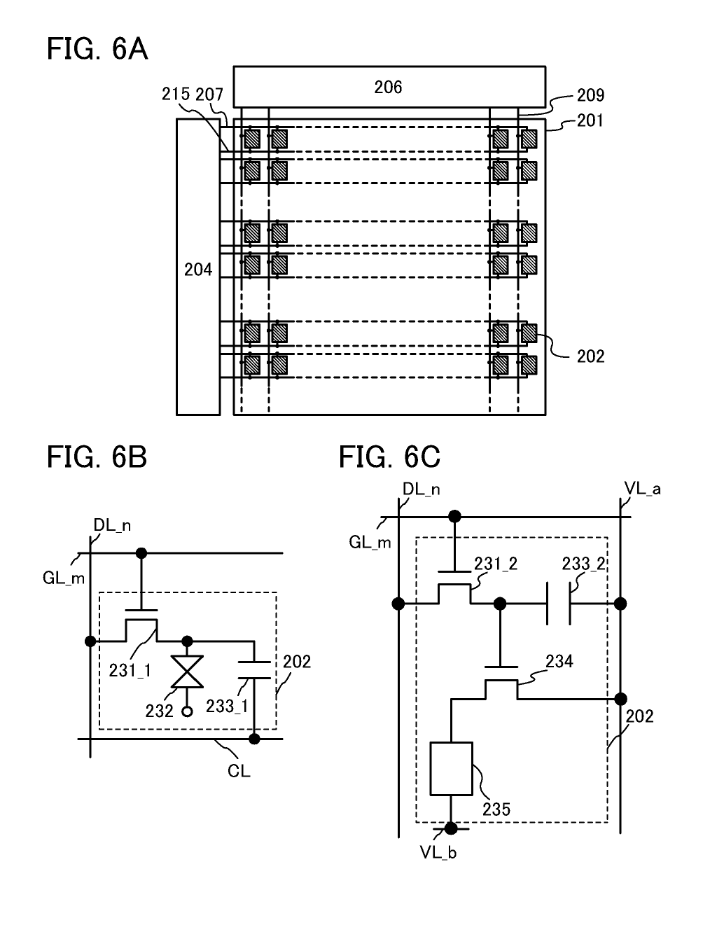

FIG. 6A illustrates an example of a semiconductor device. The semiconductor device in FIG. 6A includes a pixel portion 201, a scan line driver circuit 204, a signal line driver circuit 206, m scan lines 207 which are arranged in parallel or substantially in parallel and whose potentials are controlled by the scan line driver circuit 204, and n signal lines 209 which are arranged in parallel or substantially in parallel and whose potentials are controlled by the signal line driver circuit 206. Further, the pixel portion 201 includes a plurality of pixels 202 arranged in a matrix. Capacitor lines 215 which are arranged in parallel or almost in parallel to the scan lines 207 are also provided. The capacitor lines 215 may be arranged in parallel or almost in parallel to the signal lines 209. The scan line driver circuit 204 and the signal line driver circuit 206 are collectively referred to as a driver circuit portion in some cases.

Each scan line 207 is electrically connected to the n pixels 202 in the corresponding row among the pixels 202 arranged in m rows and n columns in the pixel portion 201. Each signal line 209 is electrically connected to the m pixels 202 in the corresponding column among the pixels 202 arranged in m rows and n columns. Note that m and n are each an integer of 1 or more. Each capacitor line 215 is electrically connected to the n pixels 202 in the corresponding row among the pixels 202 arranged in m rows and n columns. Note that in the case where the capacitor lines 215 are arranged in parallel or almost in parallel along the signal lines 209, each capacitor line 215 is electrically connected to the m pixels 202 in the corresponding column among the pixels 202 arranged in m rows and n columns.

In the semiconductor device described in Embodiment 1, the resistor having the oxide semiconductor layer is included in the driver circuit portion. Further, in the semiconductor device described in Embodiment 1, the transistor having the oxide semiconductor layer may be included in either the driver circuit portion or the pixel portion 201, or in both of them.

In the structure of this embodiment described below, the resistor having the oxide semiconductor layer described in Embodiment 1 is included in at least one of the scan line driver circuit 204 and the signal line driver circuit 206, and the transistor having the oxide semiconductor layer described in Embodiment 1 is included in the pixel 202. That is, the display device described in this embodiment is a display device in which the pixel portion 201 and the driver circuit portion (the scan line driver circuit 204 and the signal line driver circuit 206) are formed over the same substrate.

FIGS. 6B and 6C illustrate circuit configurations that can be used for the pixels 202 in the display device illustrated in FIG. 6A.

Each of the pixels 202 in FIG. 6B includes a liquid crystal element 232, a transistor 231_1, and a capacitor 233_1. The transistor 231_1 has any of the structures of the transistors described in Embodiment 1.

The potential of one of a pair of electrodes of the liquid crystal element 232 is set according to the specifications of the pixel 202 as appropriate. The alignment state of the liquid crystal element 232 depends on written data. A common potential may be applied to one of the pair of electrodes of the liquid crystal element 232 included in each of the plurality of pixel 202. Further, the potential supplied to one of a pair of electrodes of the liquid crystal element 232 in the pixel 202 in one row may be different from the potential supplied to one of a pair of electrodes of the liquid crystal element 232 in the pixel 202 in another row.

As examples of a driving method of the display device including the liquid crystal element 232, any of the following modes can be given: a TN mode, an STN mode, a VA mode, an ASM (axially symmetric aligned micro-cell) mode, an OCB (optically compensated birefringence) mode, an FLC (ferroelectric liquid crystal) mode, an AFLC (antiferroelectric liquid crystal) mode, an MVA mode, a PVA (patterned vertical alignment) mode, an IPS mode, an FFS mode, a TBA (transverse bend alignment) mode, and the like. Other examples of the driving method of the display device include ECB (electrically controlled birefringence) mode, PDLC (polymer dispersed liquid crystal) mode, PNLC (polymer network liquid crystal) mode, and a guest-host mode. Note that the present invention is not limited to this, and various liquid crystal elements and driving methods can be used as a liquid crystal element and a driving method thereof.

The liquid crystal element may be formed using a liquid crystal composition including liquid crystal exhibiting a blue phase and a chiral material. The liquid crystal exhibiting a blue phase has a short response time of 1 msec or less and is optically isotropic, which makes the alignment process unneeded and the viewing angle dependence small.

In the pixel 202 in the m-th row and the n-th column, one of a source electrode and a drain electrode of the transistor 231_1 is electrically connected to a signal line DL_n, and the other is electrically connected to the other of a pair of electrodes of the liquid crystal element 232. A gate electrode of the transistor 231_1 is electrically connected to the scan line GL_m. The transistor 231_1 has a function of controlling whether to write a data signal by being turned on or off.

One of a pair of electrodes of the capacitor 233_1 is electrically connected to a wiring to which a potential is supplied (hereinafter referred to as a capacitor line CL), and the other is electrically connected to the other of the pair of electrodes of the liquid crystal element 232. The potential of the capacitor line CL is set according to the specifications of the pixel 202 as appropriate. The capacitor 233_1 functions as a storage capacitor for retaining written data.

For example, in the display device including the pixel 202 in FIG. 6B, the pixels 202 are sequentially selected row by row by the scan line driver circuit 204, whereby the transistors 231_1 are turned on and a data signal is written.

When the transistors 231_1 are turned off, the pixel 202 in which the data has been written are brought into a holding state. This operation is sequentially performed row by row; thus, an image is displayed.

The pixel 202 illustrated in FIG. 6C includes a transistor 231_2, a capacitor 233_2, a transistor 234, and a light-emitting element 235. Any of the structures of the transistors described in Embodiment 1 is used for at least one of the transistor 231_2 and the transistor 234.

One of a source electrode and a drain electrode of the transistor 231_2 is electrically connected to a wiring to which a data signal is supplied (hereinafter referred to as signal line DL_n). A gate electrode of the transistor 231_2 is electrically connected to a wiring to which a gate signal is supplied (hereinafter referred to as a scan line GL_m).

The transistor 231_2 has a function of controlling whether to write a data signal by being turned on or off.

One of a pair of electrodes of the capacitor 233_2 is electrically connected to a wiring to which a potential is supplied (hereinafter referred to as a potential supply line VL_a), and the other is electrically connected to the other of the source electrode and the drain electrode of the transistor 231_2.

The capacitor 233_2 functions as a storage capacitor for retaining written data.

One of a source electrode and a drain electrode of the transistor 234 is electrically connected to the potential supply line VL_a. Further, a gate electrode of the transistor 234 is electrically connected to the other of the source electrode and the drain electrode of the transistor 231_2.

One of an anode and a cathode of the light-emitting element 235 is electrically connected to a potential supply line VL_b, and the other is electrically connected to the other of the source electrode and the drain electrode of the transistor 234.

The light-emitting element 235 may be an organic electroluminescent element (also referred to as organic EL element) or the like, for example. Note that the light-emitting element 235 is not limited thereto and may be an inorganic EL element containing an inorganic material.

A high power supply potential VDD is supplied to one of the potential supply line VL_a and the potential supply line VL_b, and a low power supply potential VSS is supplied to the other.

In the display device including the pixel 202 in FIG. 6C, the pixels 202 are sequentially selected row by row by the scan line driver circuit 204, whereby the transistors 231_2 are turned on and a data signal is written.

When the transistors 231_2 are turned off, the pixel 202 in which the data has been written are brought into a holding state. Further, the amount of current flowing between the source electrode and the drain electrode of the transistor 234 is controlled in accordance with the potential of the written data signal. The light-emitting element 235 emits light with a luminance corresponding to the amount of flowing current. This operation is sequentially performed row by row; thus, an image is displayed.

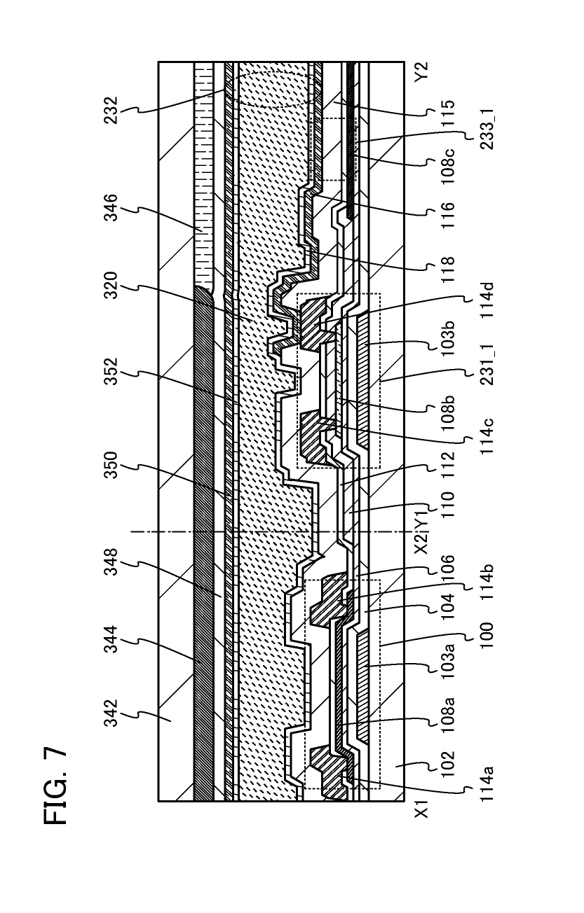

FIG. 7 is a cross-sectional view showing a specific example of a structure of a display device including the pixel 202 shown in FIG. 6B and the resistor included in the driver circuit portion. A cross section X1-X2 in FIG. 7 is a cross-sectional view of the resistor 100 included in the driver circuit portion (including the scan line driver circuit 204 and the signal line driver circuit 206). A cross section Y1-Y2 is a cross-sectional view of the transistor 231_1, the liquid crystal element 232, and the capacitor 233_1 that are included in the pixel 202. In this embodiment, a liquid crystal display device of a vertical electric field mode is described.

In the liquid crystal display device described in this embodiment, the liquid crystal element 232 is provided between a pair of substrates (the substrate 102 and a substrate 342).

The liquid crystal element 232 includes a light-transmitting conductive film 116 over the substrate 102, films controlling alignment (hereinafter referred to as alignment films 118 and 352), a liquid crystal layer 320, and a conductive film 350. Note that the light-transmitting conductive film 116 functions as one electrode of the liquid crystal element 232, and the conductive film 350 functions as the other electrode of the liquid crystal element 232.

Thus, “liquid crystal display device” refers to a device including a liquid crystal element. The liquid crystal display device includes a driver circuit for driving a plurality of pixels, for example. The liquid crystal display device may also be referred to as a liquid crystal module including a control circuit, a power supply circuit, a signal generation circuit, a backlight module, and the like provided over another substrate.

The structure of the resistor 100 included in the driver circuit portion can be the same as that described in Embodiment 1. The structure of the transistor 231_1 included in the pixel portion can be the same as that of the transistor 150 described in Embodiment 1. Note that this embodiment is not limited to this example. Other structural examples of the resistor and the transistor described in Embodiment 1 may be used for the display device.

The interlayer insulating film 115 is provided over the first source and drain electrodes 114a and 114b and the second source and drain electrodes 114c and 114d. Through the opening provided in the interlayer insulating film 115, the conductive film 116 having a light-transmitting property and functioning as a pixel electrode is connected to the second drain electrode 114d.

The interlayer insulating film 115 can be formed using an inorganic insulating material or an organic insulating material to have a single layer structure or a stacked layer structure. Note that the interlayer insulating film 115 is not necessarily provided, in which case a mask that is used to form the opening for connecting the light-transmitting conductive film 116 to the second drain electrode 114d can be omitted.

For the light-transmitting conductive film 116, a light-transmitting conductive material such as indium oxide including tungsten oxide, indium zinc oxide including tungsten oxide, indium oxide including titanium oxide, indium tin oxide including titanium oxide, ITO, indium zinc oxide, or indium tin oxide to which silicon oxide is added can be used.

Although not shown in this embodiment, the resistor 100 can have a structure in which the third gate electrode 116a is provided in a position overlapping with the first oxide semiconductor layer 108a, as in the resistor 120 in FIG. 4A. Note that the third gate electrode 116a can be formed in the same process as the light-transmitting conductive film 116 without increasing the formation steps.

One electrode of the capacitor 233_1 is formed using the third oxide semiconductor layer 108c which is formed in the same process as the first oxide semiconductor layer 108a and the second oxide semiconductor layer 108b. The other electrode of the capacitor 233_1 is formed using the light-transmitting conductive film 116. The insulating layer 112 and the interlayer insulating film 115 which are sandwiched between the pair of electrodes of the capacitor 233_1 function as a dielectric film of the capacitor 233_1.

The third oxide semiconductor layer 108c is in contact with the insulating layer 112. In this embodiment, a silicon nitride film can be used as the insulating layer 112. Hydrogen contained in the insulating layer 112 is supplied to the third oxide semiconductor layer 108c, so that the third oxide semiconductor layer 108c can serve as a light-transmitting conductive layer. Note that the resistance values of the first, second, third oxide semiconductor layers 108a, 108b, and 108c are preferably different from one another. For example, the resistance values are preferably increased in the following order: the third oxide semiconductor layer 108c, the first oxide semiconductor layer 108a, and the second oxide semiconductor layer 108b. In order to set the resistance values in this order, for example, plasma treatment is performed on the first oxide semiconductor layer 108a to reduce the resistance of the first oxide semiconductor layer 108a, oxygen is supplied from the insulating layer 110 to the second oxide semiconductor layer 108b to repair oxygen vacancies and increase the resistance of the second oxide semiconductor layer 108b, and hydrogen is supplied from the insulating layer 112 to the third oxide semiconductor layer 108c to reduce the resistance of the third oxide semiconductor layer 108c. Note that the order of the resistance values of the first, second, and third oxide semiconductor layers 108a, 108b, and 108c is not limited to the above. For example, the resistance value of the first oxide semiconductor layer 108a may be equal to that of the third oxide semiconductor layer 108c.

In FIG. 7, the capacitor 233_1 can be formed large (in a large area) in the pixel by forming both of the electrodes and a dielectric film sandwiched between the pair of electrodes with the use of light-transmitting materials. Thus, a display device having an increased charge capacity as well as an aperture ratio increased to typically 55% or more, preferably 60% or more can be provided.

A film having a colored property (hereinafter referred to as a colored film 346) is formed on the lower surface of the substrate 342. The colored film 346 functions as a color filter. Further, a light-blocking film 344 adjacent to the colored film 346 is formed on the lower surface of the substrate 342. The light-blocking film 344 functions as a black matrix. The colored film 346 is not necessarily provided in the case where the display device is a monochrome display device, for example.

The colored film 346 is a colored film that transmits light in a specific wavelength range. For example, a red (R) color filter for transmitting light in a red wavelength range, a green (G) color filter for transmitting light in a green wavelength range, a blue (B) color filter for transmitting light in a blue wavelength range, or the like can be used.

The light-blocking film 344 preferably has a function of blocking light in a particular wavelength region, and can be a metal film or an organic insulating film including a black pigment.

An insulating layer 348 is formed on the lower surface of the colored film 346. The insulating layer 348 functions as a planarization layer or suppresses diffusion of impurities in the colored film 346 to the liquid crystal element side.

The conductive film 350 is formed on the lower surface of the insulating layer 348. The conductive film 350 functions as the other of the pair of electrodes of the liquid crystal element 232 in the pixel portion.

The alignment films 118 and 352 can be formed by a rubbing method, an optical alignment method, or the like.

In addition, a liquid crystal layer 320 is formed between the alignment films 118 and 352. The liquid crystal layer 320 is sealed between the substrate 102 and the substrate 342 with the use of a sealant (not illustrated). The sealant is preferably in contact with an inorganic material to prevent entry of moisture and the like from the outside. The liquid crystal layer 320 can be formed by a dispenser method (a dropping method), or an injecting method by which a liquid crystal is injected using a capillary phenomenon after the substrate 102 and the substrate 342 are bonded to each other.

A spacer may be provided between the light-transmitting conductive film 116 and the conductive film 350, and the light-transmitting conductive film 116 and the conductive film 350 to maintain the thickness of the liquid crystal layer 320 (also referred to as a cell gap).

In the display device in this embodiment, a transistor included in a driver circuit portion and/or a pixel circuit portion and a resistor included in the driver circuit portion can be formed over the same substrate at the same time. Thus, the resistor can be formed without increasing the manufacturing cost and the like.

The structures, the methods, and the like described in this embodiment can be combined as appropriate with any of the structures, the methods, and the like described in the other embodiments.

### Embodiment 4

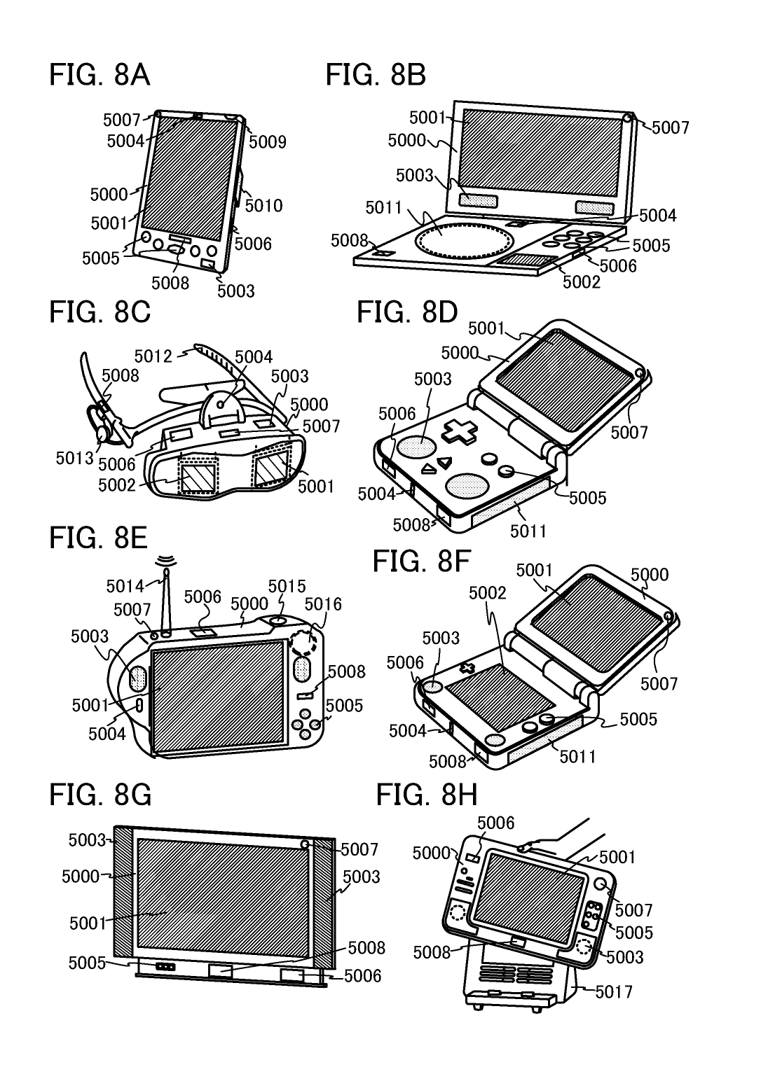

In this embodiment, structural examples of electronic devices in which a semiconductor device is included in a display portion of one embodiment of the present invention are described with reference to FIGS. 8A to 8H.

FIGS. 8A to 8H illustrate electronic devices. These electronic devices can include a housing 5000, a display portion 5001, a speaker 5003, an LED lamp 5004, operation keys 5005 (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, and the like.

FIG. 8A illustrates a mobile computer, which includes a switch 5009, an infrared port 5010, and the like in addition to the above components. FIG. 8B illustrates a portable image reproducing device provided with a memory medium (e.g., a DVD reproducing device), which can include a second display portion 5002, a memory medium reading portion 5011, and the like in addition to the above objects. FIG. 8C illustrates a goggle-type display, which includes the second display portion 5002, a support 5012, an earphone 5013, and the like in addition to the above components. FIG. 8D illustrates a portable game machine that can include the memory medium reading portion 5011 and the like in addition to the above components. FIG. 8E illustrates a digital camera which has a television reception function and can include an antenna 5014, a shutter button 5015, an image receiving portion 5016, and the like in addition to the above components. FIG. 8F shows a portable game machine that can include the second display portion 5002, the memory medium reading portion 5011, and the like in addition to the above objects. FIG. 8G illustrates a television receiver which can include a tuner, an image processing portion, and the like in addition to the above objects. FIG. 8H illustrates a portable television receiver, which can include a charger 5017 capable of transmitting and receiving signals and the like in addition to the above objects.

The electronic devices illustrated in FIGS. 8A to 8H can have a variety of functions. For example, a function of displaying a variety of information (e.g., a still image, a moving image, and a text image) on a display portion, a touch panel function, a function of displaying a calendar, date, time, and the like, a function of controlling processing with a variety of software (programs), a wireless communication function, a function of being connected to a variety of computer networks with a wireless communication function, a function of transmitting and receiving a variety of data with a wireless communication function, and a function of reading program or data stored in a recording medium and displaying the program or data on a display portion. Further, the electronic device including a plurality of display portions can have a function of displaying image information mainly on one display portion while displaying text information on another display portion, a function of displaying a three-dimensional image by displaying images where parallax is considered on a plurality of display portions, or the like. Furthermore, the electronic device including an image receiving portion can have a function of photographing a still image, a function of photographing a moving image, a function of automatically or manually correcting a photographed image, a function of storing a photographed image in a memory medium (an external memory medium or a memory medium incorporated in the camera), a function of displaying a photographed image on the display portion, or the like. Note that functions which can be provided for the electronic devices shown in FIGS. 8A to 8H are not limited thereto, and the electronic devices can have a variety of functions.

The electronic devices described in this embodiment have a feature that they have the semiconductor device of the present invention in a display portion for displaying some sort of information.

The structures, the methods, and the like described in this embodiment can be combined as appropriate with any of the structures, the methods, and the like described in the other embodiments.

### Example 1

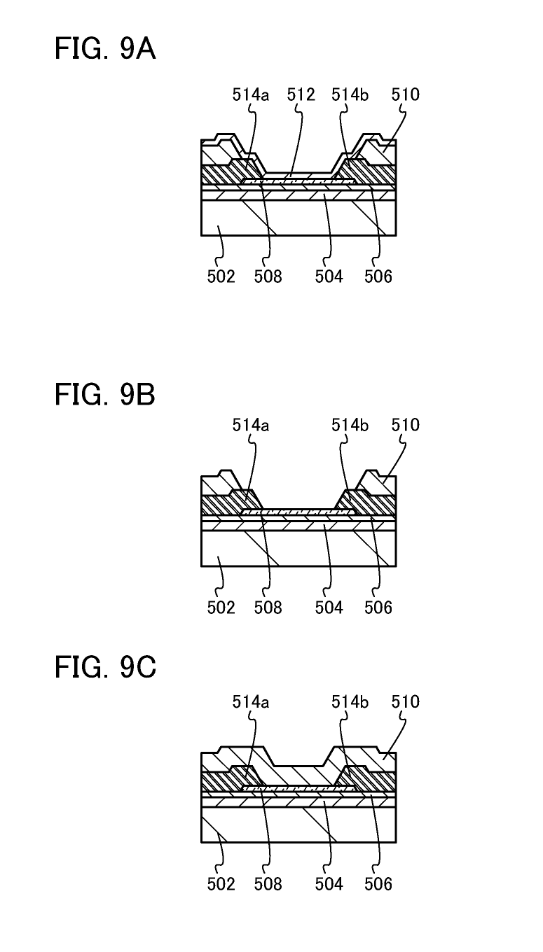

In Example 1, to fabricate Sample 1 to Sample 9, samples having structures shown in FIGS. 9A to 9C were fabricated and conditions for the samples such as plasma treatment conditions were changed. Then, sheet resistances of oxide semiconductor layers included in Sample 1 to Sample 9 were evaluated. The structures shown in FIG. 9A to 9C will be described and then Sample 1 to Sample 9 will be described.

### (Structure A)

The structure in FIG. 9A is referred to as Structure A. The sample having the structure in FIG. 9A includes a substrate 502, insulating layers 504 and 506 over the substrate 502, an oxide semiconductor layer 508 over the insulating layer 506, conductive layers 514a and 514b over the insulating layer 506 and the oxide semiconductor layer 508, an insulating layer 510 over the conductive layers 514a and 514b, and an insulating layer 512 covering the oxide semiconductor layer 508, the insulating layer 510, and the conductive layers 514a and 514b.

### (Structure B)

The structure in FIG. 9B is referred to as Structure B. The sample having the structure in FIG. 9B includes the substrate 502, the insulating layers 504 and 506 over the substrate 502, the oxide semiconductor layer 508 over the insulating layer 506, the conductive layers 514a and 514b over the insulating layer 506 and the oxide semiconductor layer 508, and the insulating layer 510 over the conductive layers 514a and 514b. Structure B is different from Structure A in that the insulating layer 512 is not formed.

### (Structure C)

The structure in FIG. 9C is referred to as Structure C. The sample having the structure in FIG. 9C includes the substrate 502, the insulating layers 504 and 506 over the substrate 502, the oxide semiconductor layer 508 over the insulating layer 506, the conductive layers 514a and 514b over the insulating layer 506 and the oxide semiconductor layer 508, and the insulating layer 510 covering the oxide semiconductor layer 508 and the conductive layers 514a and 514b. In Structure C, the insulating layer 510 has a shape different from that of the insulating layer 510 in Structure A and the insulating layer 512 is not formed. Further, in Structure C, heat treatment was performed at 350° C. in a mixed gas atmosphere of nitrogen and oxygen for one hour after the insulating layer 510 was formed.

Here, materials and formation conditions for Structures A, B, and C will be described.

A glass substrate was used as the substrate 502.

A silicon nitride film was used for the insulating layer 504. Three silicon nitride films formed under different conditions were stacked as the silicon nitride film. The formation conditions of a first silicon nitride film were as follows: the electric power (RF)=2000 W; the pressure=100 Pa; SiH₄/N₂/NH₃=200/2000/100 sccm; and the film thickness=50 nm. The formation conditions of a second silicon nitride film were as follows: the electric power (RF)=2000 W; the pressure=100 Pa; SiH₄/N₂/NH₃=200/2000/2000 sccm; and the film thickness=300 nm. The formation conditions of a third silicon nitride film were as follows: the electric power (RF)=2000 W; the pressure=100 Pa; SiH₄/N₂=200/5000 sccm; and the film thickness=50 nm Note that all of the first to the third silicon nitride films were formed at a substrate temperature of 350° C. using a PE-CVD apparatus.

A silicon oxynitride film was used as the insulating layer 506. The formation conditions of the silicon oxynitride film were as follows: the electric power (RF)=100 W; the pressure=100 Pa; SiH₄/N₂O=20/3000 sccm; and the film thickness=50 nm. Note that the silicon oxynitride film was formed at a substrate temperature of 350° C. using a PE-CVD apparatus.

The oxide semiconductor layer 508 was formed by sputtering using a target with a proportion where In:Ga:Zn=1:1:1. The formation conditions were as follows: the electric power (DC)=3 kW; the pressure=0.6 Pa; Ar/O₂=60/140 sccm (O₂=70%); the substrate temperature=200° C.; and the film thickness=35 nm.

As the insulating layer 510, a silicon oxynitride film was used. Two silicon oxynitride films formed under different conditions were stacked as the silicon oxy nitride film. The formation conditions of the first silicon oxynitride film were as follows: the electric power (RF)=150 W; the pressure=200 Pa; SiH₄/N₂O=20/3000 sccm; and the film thickness=50 nm. The formation conditions of the second silicon oxynitride film were as follows: the electric power (RF)=1500 W; the pressure=200 Pa; SiH₄/N₂O=160/4000 sccm; and the film thickness=400 nm Note that the first silicon oxynitride film and the second silicon oxynitride film were formed at 350° C. and 220° C., respectively.

A silicon nitride film was used as the insulating layer 512. The formation conditions of the silicon nitride film were as follows: the electric power (RF)=1000 W; the pressure=200 Pa; SiH₄/N₂/NH₃=50/5000/100 sccm; and the film thickness=100 nm Note that the silicon nitride film was formed at a substrate temperature of 350° C. using a PE-CVD apparatus.

The conductive layers 514a and 514b has a three-layer structure including a tungsten film (50 nm), an aluminum film (400 nm), and a titanium film (100 nm). Note that the tungsten film, the aluminum film, and the titanium film were formed by sputtering.

### (Sample 1)

A sample having Structure A was used as Sample 1. That is, Sample 1 has a structure in which the oxide semiconductor layer 508 is in contact with the silicon nitride film as the insulating layer 512.

### (Sample 2)

A sample having Structure B was used as Sample 2. That is, Sample 2 has a structure in which the surface of the oxide semiconductor layer 508 is exposed. In addition, Structure B of Sample 2 was subjected to Ar plasma treatment. The conditions for the Ar plasma treatment were as follows: the electric power (RF)=1000 W; the pressure=200 Pa; Ar=2000 sccm; the treatment time=300 sec; and the substrate temperature=350° C.

### (Sample 3)

A sample having Structure B was used as Sample 3. That is, Sample 3 has a structure in which the surface of the oxide semiconductor layer 508 is exposed. In addition, Structure B of Sample 3 was subjected to Ar+NH₃ plasma treatment. The conditions for the Ar+NH₃ plasma treatment were as follows: the electric power (RF)=1000 W; the pressure=200 Pa; Ar+NH₃=2000/2000 sccm; the treatment time=300 sec; and the substrate temperature=350° C.

### (Sample 4)

A sample having Structure B was used as Sample 4. That is, Sample 4 has a structure in which the surface of the oxide semiconductor layer 508 is exposed. In addition, Structure B of Sample 4 was subjected to NH₃ plasma treatment. The conditions for the NH₃ plasma treatment were as follows: the electric power (RF)=1000 W; the pressure=200 Pa; NH₃=2000 sccm; the treatment time=300 sec; and the substrate temperature=350° C.

### (Sample 5)

A sample having Structure B was used as Sample 5. That is, Sample 5 has a structure in which the surface of the oxide semiconductor layer 508 is exposed. In addition, Structure B of Sample 5 was subjected to N₂ plasma treatment. The conditions for the N₂ plasma treatment were as follows: the electric power (RF)=1000 W; the pressure=200 Pa; N₂=2000 sccm; the treatment time=300 sec; and the substrate temperature=350° C.

### (Sample 6)

A sample having Structure C was used as Sample 6. That is, Sample 6 has a structure in which the surface of the oxide semiconductor layer 508 is covered by the insulating layer 510. In addition, Structure C of Sample 6 was subjected to Ar plasma treatment. The conditions for the Ar plasma treatment were as follows: the electric power (RF)=1000 W; the pressure=200 Pa; Ar=2000 sccm; the treatment time=300 sec; and the substrate temperature=350° C.

### (Sample 7)

A sample having Structure C was used as Sample 7. That is, Sample 7 has a structure in which the surface of the oxide semiconductor layer 508 is covered by the insulating layer 510. In addition, Structure C of Sample 7 was subjected to Ar+NH₃ plasma treatment. The conditions for the Ar+NH₃ plasma treatment were as follows: the electric power (RF)=1000 W; the pressure=200 Pa; Ar+NH₃=2000/2000 sccm; the treatment time=300 sec; and the substrate temperature=350° C.

### (Sample 8)

A sample having Structure C was used as Sample 8. That is, Sample 8 has a structure in which the surface of the oxide semiconductor layer 508 is covered by the insulating layer 510. In addition, Structure C of Sample 8 was subjected to NH₃ plasma treatment. The conditions for the NH₃ plasma treatment were as follows: the electric power (RF)=1000 W; the pressure=200 Pa; NH₃=2000 sccm; the treatment time=300 sec; and the substrate temperature=350° C.

### (Sample 9)

A sample having Structure C was used as Sample 9. That is, Sample 9 has a structure in which the surface of the oxide semiconductor layer 508 is covered by the insulating layer 510. In addition, Structure C of Sample 9 was subjected to N₂ plasma treatment. The conditions for the N₂ plasma treatment were as follows: the electric power (RF)=1000 W; the pressure=200 Pa; N₂=2000 sccm; the treatment time=300 sec; and the substrate temperature=350° C.

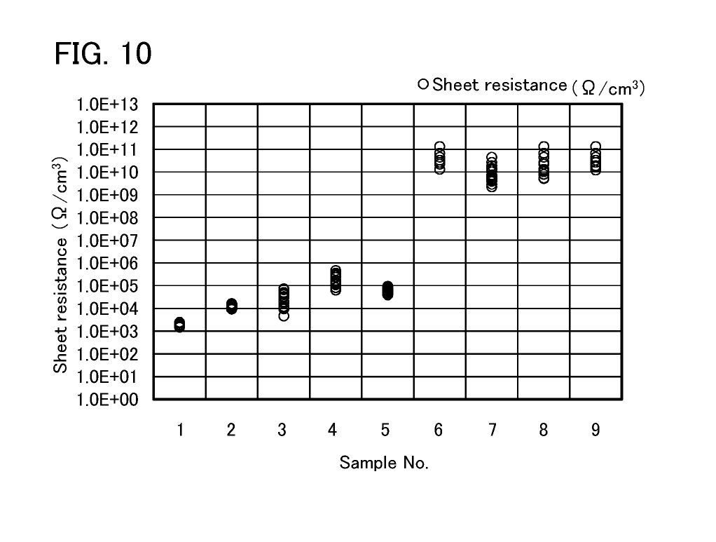

The sheet resistances of Sample 1 to Sample 9 were measured. FIG. 10 shows measurement results of the sheet resistances.

Note that the sheet resistance of each sample in FIG. 10 is shown by plotting 20 data.

As shown in FIG. 10, the sheet resistance of Sample 1 was approximately 1.9×10³ Ω/cm³. The sheet resistance of Sample 2 was approximately 1.2×10⁴ Ω/cm³. The sheet resistance of Sample 3 was approximately 2.9×10⁴ Ω/cm³. The sheet resistance of Sample 4 was approximately 1.9×10⁵ Ω/cm³. The sheet resistance of Sample 5 was approximately 6.2×10⁴ Ω/cm³. The sheet resistance of Sample 6 was approximately 3.5×10¹³ Ω/cm³. The sheet resistance of Sample 7 was approximately 1.0×10¹⁰ Ω/cm³. The sheet resistance of Sample 8 was approximately 5.0×10¹² Ω/cm³. The sheet resistance of Sample 9 was approximately 4.7×10¹³ Ω/cm³.

In Sample 1, the oxide semiconductor layer is in contact with the silicon nitride film. With this structure, hydrogen contained in the silicon nitride film is supplied to the oxide semiconductor layer to reduce the resistance of the oxide semiconductor layer. In Samples 2 to 5, because the surface of the oxide semiconductor layer is exposed, oxygen vacancies are generated in the oxide semiconductor layer by the plasma treatment and hydrogen is combined with the oxygen vacancies, so that the resistance is reduced. On the other hand, in Samples 6 to 9, the surface of the oxide semiconductor layer is covered by the insulating layer. Thus, although the plasma treatment similar to that was performed for forming Samples 2 to 5 is performed, the sheet resistance of the oxide semiconductor layer is not reduced but increased.

These results show that the sheet resistance of the oxide semiconductor layer was able to be controlled by changing the material of the film that is in contact with the oxide semiconductor layer and/or by performing plasma treatment on the oxide semiconductor layer.

### Example 2

In Example 2, a defect in an oxide semiconductor layer will be described. The defect in the oxide semiconductor layer was measured by electron spin resonance (ESR).

In Example 2, Samples 10 to 14 were fabricated, which will be described below.

### (Sample 10)

Sample 10 has a structure in which a 100-nm-thick oxide semiconductor layer is formed over a quartz substrate. The oxide semiconductor layer was formed by a sputtering method using a target with a proportion where In:Ga:Zn=1:1:1. The formation conditions were as follows: the electric power (DC)=3 kW; the pressure=0.6 Pa; Ar/O₂=60/140 sccm (O₂=70%); and the substrate temperature=200° C. Then, a silicon nitride film was formed over the oxide semiconductor layer. The formation conditions of the silicon nitride film were as follows: the electric power (RF)=1000 W; the pressure=200 Pa; SiH₄/N₂/NH₃=50/5000/100 sccm; and the film thickness=100 nm. Note that the silicon nitride film was formed at a substrate temperature of 350° C. using a PE-CVD apparatus. Then, the silicon nitride film over the oxide semiconductor layer was removed, so that the surface of the oxide semiconductor layer was exposed.

### (Sample 11)

Sample 11 has a structure in which a 100-nm-thick oxide semiconductor layer is formed over a quartz substrate. The oxide semiconductor layer was formed in the same formation conditions as that of Sample 10. Then, Ar plasma treatment was performed on the oxide semiconductor layer. The conditions for the Ar plasma treatment were as follows: the electric power (RF)=1000 W; the pressure=200 Pa; Ar=2000 sccm; the treatment time=300 sec; and the substrate temperature=350° C.

### (Sample 12)

Sample 12 has a structure in which a 100-nm-thick oxide semiconductor layer is formed over a quartz substrate. The oxide semiconductor layer was formed in the same formation conditions as that of Sample 10. Then, Ar+NH₃ plasma treatment was performed on the oxide semiconductor layer. The conditions for the Ar+NH₃ plasma treatment were as follows: the electric power (RF)=1000 W; the pressure=200 Pa; Ar+NH₃=2000/2000 sccm; the treatment time=300 sec; and the substrate temperature=350° C.

### (Sample 13)

Sample 13 has a structure in which a 100-nm-thick oxide semiconductor layer is formed over a quartz substrate. The oxide semiconductor layer was formed in the same formation conditions as that of Sample 10. Then, NH₃ plasma treatment was performed on the oxide semiconductor layer. The conditions for the NH₃ plasma treatment were as follows: the electric power (RF)=1000 W; the pressure=200 Pa; NH₃=2000 sccm; the treatment time=300 sec; and the substrate temperature=350° C.

### (Sample 14)

Sample 14 has a structure in which a 100-nm-thick oxide semiconductor layer is formed over a quartz substrate. The oxide semiconductor layer was formed in the same formation conditions as that of Sample 10. Then, N₂ plasma treatment was performed on the oxide semiconductor layer. The conditions for the N₂ plasma treatment were as follows: the electric power (RF)=1000 W; the pressure=200 Pa; N₂=2000 sccm; the treatment time=300 sec; and the substrate temperature=350° C.

Samples 10 to 14 fabricated in the above-described manner were subjected to ESR measurements. The conditions of the ESR measurement are as follows. The measurement temperature was room temperature (25° C.), a high-frequency power (microwave power) of 9.2 GHz was 40 mW, and the direction of a magnetic field was parallel to a surface of the oxide semiconductor layer of Sample. The spin density of a signal that appears around g=1.93 which is due to oxygen vacancies in the oxide semiconductor layer was measured. Note that the lower limit of the detection of the spin densities of the signal that appears around g=1.93 was 1.0×10¹⁷ spins/cm³.

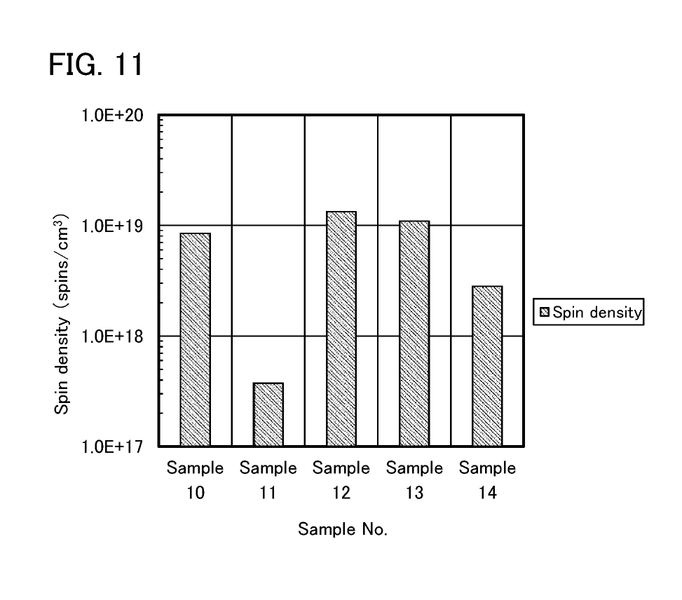

Results of the ESR measurements are shown in FIG. 11. As shown in FIG. 11, the spin density of Sample 10 was approximately 8.5×10¹⁸ spins/cm³. The spin density of Sample 11 was approximately 3.8×10¹⁷ spins/cm³. The spin density of Sample 12 was approximately 1.3×10¹⁹ spins/cm³. The spin density of Sample 13 was approximately 1.1×10¹⁹ spins/cm³. The spin density of Sample 14 was approximately 2.8×10¹⁸ spins/cm³.

The results show that the oxygen vacancies in the oxide semiconductor layers are changed by the plasma treatment on the oxide semiconductor layers.

### Example 3

In Example 3, hydrogen concentration in an oxide semiconductor layer will be described. The hydrogen concentration in the oxide semiconductor layer was analyzed by SIMS.

In Example 3, Samples 15 to 19 were fabricated, which will be described below.

### (Sample 15)

Sample 15 has a structure in which a 100-nm-thick oxide semiconductor layer and a 100-nm-thick silicon nitride layer are stacked over a quartz substrate. The oxide semiconductor layer was formed by a sputtering method using a target with a proportion where In:Ga:Zn=1:1:1. The formation conditions were as follows: the electric power (DC)=3 kW; the pressure=0.6 Pa; Ar/O₂=60/140 sccm (O₂=70%); and the substrate temperature=200° C. The formation conditions of the silicon nitride film were as follows: the electric power (RF)=1000 W; the pressure=200 Pa; SiH₄/N₂/NH₃=50/5000/100 sccm; the film thickness=100 nm, and the substrate temperature=350° C.

### (Sample 16)

Sample 16 has a structure in which a 100-nm-thick oxide semiconductor layer is formed over a quartz substrate. The oxide semiconductor layer was formed in the same formation conditions as that of Sample 15. Then, Ar plasma treatment was performed on the oxide semiconductor layer. The conditions for the Ar plasma treatment were as follows: the electric power (RF)=1000 W; the pressure=200 Pa; Ar=2000 sccm; the treatment time=300 sec; and the substrate temperature=350° C.

### (Sample 17)

Sample 17 has a structure in which a 100-nm-thick oxide semiconductor layer is formed over a quartz substrate. The oxide semiconductor layer was formed in the same formation conditions as that of Sample 15. Then, Ar+NH₃ plasma treatment was performed on the oxide semiconductor layer. The conditions for the Ar+NH₃ plasma treatment were as follows: the electric power (RF)=1000 W; the pressure=200 Pa; Ar+NH₃=2000/2000 sccm; the treatment time=300 sec; and the substrate temperature=350° C.

### (Sample 18)

Sample 18 has a structure in which a 100-nm-thick oxide semiconductor layer is formed over a quartz substrate. The oxide semiconductor layer was formed in the same formation conditions as that of Sample 15. Then, NH₃ plasma treatment was performed on the oxide semiconductor layer. The conditions for the NH₃ plasma treatment were as follows: the electric power (RF)=1000 W; the pressure=200 Pa; NH₃=2000 sccm; the treatment time=300 sec; and the substrate temperature=350° C.

### (Sample 19)

Sample 19 has a structure in which a 100-nm-thick oxide semiconductor layer is formed over a quartz substrate. The oxide semiconductor layer was formed in the same formation conditions as that of Sample 15. Then, N₂ plasma treatment was performed on the oxide semiconductor layer. The conditions for the N₂ plasma treatment were as follows: the electric power (RF)=1000 W; the pressure=200 Pa; N₂=2000 sccm; the treatment time=300 sec; and the substrate temperature=350° C.

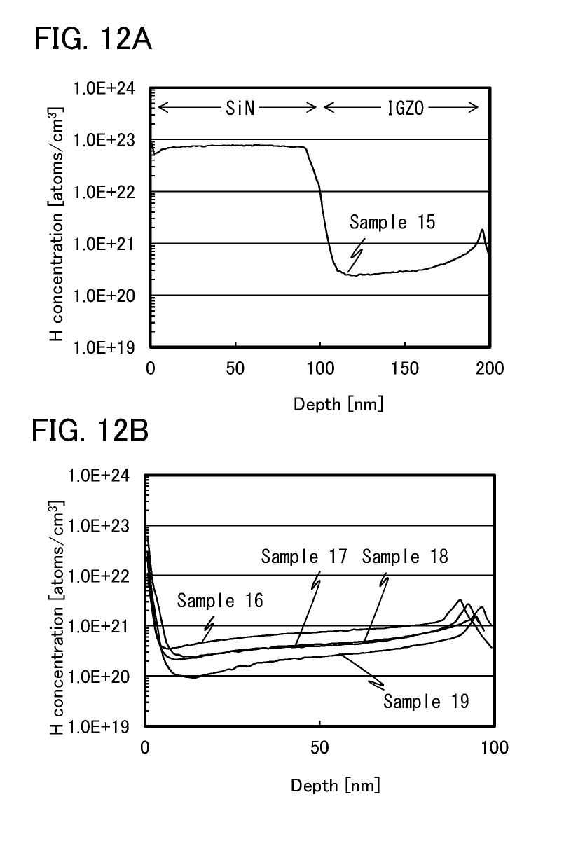

The hydrogen concentration in each of the oxide semiconductor layers of Samples 15 to 19 fabricated in the above-described manner was analyzed by SIMS. FIGS. 12A and 12B show results of the SIMS analysis. Note that measurement results of Samples 17 and 18 partly overlap with each other in FIG. 12B.

As shown in FIG. 12A, the hydrogen concentration in the oxide semiconductor layer of Sample 15 was approximately 2.9×10²⁰ atoms/cm³. As shown in FIG. 12B, the hydrogen concentration in the oxide semiconductor layer of Sample 16 was approximately 7.4×10²⁰ atoms/cm³, the hydrogen concentration in the oxide semiconductor layer of Sample 17 was approximately 4.3×10²⁰ atoms/cm³, the hydrogen concentration in the oxide semiconductor layer of Sample 18 was approximately 3.9×10²⁰ atoms/cm³, and the hydrogen concentration in the oxide semiconductor layer of Sample 19 was approximately 2.4×10²⁰ atoms/cm³.

Note that the above values of the hydrogen concentrations in the oxide semiconductor layers of Samples 15 to 19 were measured at a depth of approximately 50 nm.

These results show that a difference in hydrogen concentration among the oxide semiconductor layers is produced by performing the plasma treatment on the oxide semiconductor layers and/or by changing the material of the film that is contact with the oxide semiconductor layer. Further, the results of Samples 15 to 19 in FIGS. 12A and 12B show that the hydrogen concentration in the oxide semiconductor layer is 1.0×10²⁰ atoms/cm³ or higher by performing the plasma treatment on the oxide semiconductor layer and/or by providing the silicon nitride film in contact with the oxide semiconductor layer.

This application is based on Japanese Patent Application serial no. 2013-081882 filed with Japan Patent Office on Apr. 10, 2013, the entire contents of which are hereby incorporated by reference.

What is claimed is:

1. A semiconductor device comprising a resistor and a transistor over the same substrate,
wherein the resistor comprises:
a first gate electrode;
a first oxide semiconductor layer;
a first gate insulating layer between the first gate electrode and the first oxide semiconductor layer; and
wherein the transistor comprises:
a second gate electrode;
a second oxide semiconductor layer;
a second gate insulating layer between the second gate electrode and the second oxide semiconductor layer; and
wherein a carrier density of the first oxide semiconductor layer is higher than a carrier density of the second oxide semiconductor layer.

2. The semiconductor device according to claim 1,
wherein the resistor further comprises a first source electrode and a first drain electrode electrically connected to the first oxide semiconductor layer,
wherein the transistor further comprises a second source electrode and a second drain electrode electrically connected to the second oxide semiconductor layer, and
wherein the resistor and the transistor further comprise:
an interlayer insulating film over the first source electrode, the first drain electrode, the second source electrode, and the second drain electrode;
a third gate electrode overlapping the first oxide semiconductor layer over the interlayer insulating film; and
a fourth gate electrode overlapping the second oxide semiconductor layer over the interlayer insulating film.

3. The semiconductor device according to claim 1, further comprising:
a driver circuit portion including the resistor; and
a pixel portion including the transistor.

4. A semiconductor device comprising a resistor and a transistor over the same substrate,
wherein the resistor comprises:
a first gate electrode;
a first gate insulating layer over the first gate electrode;
a first oxide semiconductor layer overlapping the first gate electrode over the first gate insulating layer; and
a first source electrode and a first drain electrode electrically connected to the first oxide semiconductor layer,
wherein the transistor comprises:
a second gate electrode;
a second gate insulating layer over the second gate electrode;
a second oxide semiconductor layer overlapping the second gate electrode over the second gate insulating layer; and
a second source electrode and a second drain electrode electrically connected to the second oxide semiconductor layer,
wherein the first oxide semiconductor layer and the second oxide semiconductor layer have the same composition, and
wherein a carrier density of the first oxide semiconductor layer is higher than a carrier density of the second oxide semiconductor layer.

5. The semiconductor device according to claim 4,
wherein the resistor and the transistor further comprise:
an interlayer insulating film over the first source electrode, the first drain electrode, the second source electrode, and the second drain electrode;
a third gate electrode overlapping the first oxide semiconductor layer over the interlayer insulating film; and
a fourth gate electrode overlapping the second oxide semiconductor layer over the interlayer insulating film.

6. The semiconductor device according to claim 4, further comprising:
a driver circuit portion including the resistor; and
a pixel portion including the transistor.

7. A semiconductor device comprising a resistor and a transistor over the same substrate,
wherein the resistor comprises:
a first gate electrode;
a first gate insulating layer over the first gate electrode;
a first source electrode and a first drain electrode over the first gate insulating layer; and
a first oxide semiconductor layer over the first gate insulating layer, the first source electrode, and the first drain electrode,
wherein the transistor comprises:
a second gate electrode;
a second gate insulating layer over the second gate electrode;
a second source electrode and a second drain electrode over the second gate insulating layer;
a second oxide semiconductor layer over the second gate insulating layer, the second source electrode, and the second drain electrode,
wherein the first oxide semiconductor layer and the second oxide semiconductor layer have the same composition, and
wherein a carrier density of the first oxide semiconductor layer is higher than a carrier density of the second oxide semiconductor layer.

8. The semiconductor device according to claim 7, further comprising:
a driver circuit portion including the resistor; and
a pixel portion including the transistor.

9. A semiconductor device comprising a resistor and a transistor over the same substrate,
wherein the resistor comprises:
a first source electrode and a first drain electrode;
a first oxide semiconductor layer over the first source electrode and the first drain electrode;
a third gate insulating layer over the first oxide semiconductor layer; and
a third gate electrode overlapping the first oxide semiconductor layer over the third gate insulating layer,
wherein the transistor comprises:
a second gate electrode;
a second gate insulating layer over the second gate electrode;
a second source electrode and a second drain electrode over the second gate insulating layer;
a second oxide semiconductor layer over the second gate insulating layer, the second source electrode, and the second drain electrode,
wherein the first oxide semiconductor layer and the second oxide semiconductor layer have the same composition, and
wherein a carrier density of the first oxide semiconductor layer is higher than a carrier density of the second oxide semiconductor layer.

10. The semiconductor device according to claim 9, further comprising:
a driver circuit portion including the resistor; and
a pixel portion including the transistor.
